(19) United States
(12) Patent Application Publication
(10) Pub. No.: US 2024/0310740 A1
(43) Pub. Date: Sep. 19, 2024

(54) SUBSTRATE TRANSFER METHOD AND SUBSTRATE TRANSFER APPARATUS

(71) Applicant: Tokyo Electron Limited, Tokyo (JP)

(72) Inventors: Kenichirou MATSUYAMA, Koshi City (JP); Hiroki TADATOMO, Tokyo (JP); Yoji SAKATA, Koshi City (JP); Shinsuke TAKAKI, Koshi City (JP)

(21) Appl. No.: 18/599,619

(22) Filed: Mar. 8, 2024

(30) Foreign Application Priority Data
Mar. 14, 2023 (JP) 2023-040002

(51) Int. Cl. G03F 7/00; B65G 47/90; G03F 7/38; H01L 21/677

(52) U.S. Cl. CPC G03F 7/7075; B65G 47/90; G03F 7/38; G03F 7/70533; G03F 7/7085; G03F 7/70875; G03F 7/70991; H01L 21/67703

(57) ABSTRACT

A substrate transfer method of transferring a substrate on which a metal-containing resist film is formed from a first placement part to a second placement part, includes transferring, depending on an abnormality in a transfer path, the substrate to a standby chamber in which a second atmosphere different from a first atmosphere of the first placement part is formed, without transferring the substrate to the second placement part, and putting the substrate on standby in the second atmosphere.

### CROSS-REFERENCE TO RELATED APPLICATION

This application is based upon and claims the benefit of priority from Japanese Patent Application No. 2023-040002, filed on Mar. 14, 2023, the entire contents of which are incorporated herein by reference.

### TECHNICAL FIELD

The present disclosure relates to a substrate transfer method and a substrate transfer apparatus.

### BACKGROUND

In manufacturing semiconductor devices, photolithography is performed on semiconductor wafers (hereinafter, referred to as “wafers”). As a resist used in this photolithography, a metal-containing resist is sometimes used, and Patent Document 1 discloses an apparatus for forming a resist film with the resist and developing the resist film after exposure. It is described that in order to reduce the difference in the moisture content among the resist films of respective wafers at the time of post-exposure heating, this apparatus is equipped with a substrate accommodation unit in which a plurality of unexposed wafers can be put on standby after resist film formation and the internal humidity (moisture content) thereof can be adjusted.

### PRIOR ART DOCUMENTS

### Patent Documents

Patent Document 1: Japanese Patent Laid-Open Publication No. 2020-119961

### SUMMARY

According to one embodiment of the present disclosure, a substrate transfer method of transferring a substrate on which a metal-containing resist film is formed from a first placement part to a second placement part, includes transferring, depending on an abnormality in a transfer path, the substrate to a standby chamber in which a second atmosphere different from a first atmosphere of the first placement part is formed, without transferring the substrate to the second placement part, and putting the substrate on standby in the second atmosphere.

### BRIEF DESCRIPTION OF DRAWINGS

The accompanying drawings, which are incorporated in and constitute a part of the specification, illustrate embodiments of the present disclosure, and together with the general description given above and the detailed description of the embodiments given below, serve to explain the principles of the present disclosure.

FIG. 1 is a plan view of a coating/developing apparatus according to a first embodiment of a substrate processing apparatus of the present disclosure.

FIG. 2 is a vertical cross-sectional front view of the coating/developing apparatus.

FIG. 3 is a perspective view of a buffer module provided in the coating/developing apparatus.

FIG. 4 is a perspective view of the buffer module.

FIG. 5 is a perspective view of the buffer module.

FIGS. 6A to 6C are a schematic side views of the buffer module.

FIGS. 7A to 7C are an explanatory views illustrating a wafer transfer path in the coating/developing apparatus.

FIG. 8 is an explanatory view illustrating an example of transferring an unexposed wafer when an abnormality occurs.

FIG. 9 is an explanatory view illustrating an example of transferring an unexposed wafer when an abnormality occurs.

FIG. 10 is an explanatory view illustrating an example of transferring an unexposed wafer when an abnormality is resolved.

FIG. 11 is an explanatory view illustrating an example of transferring an unexposed wafer when an abnormality occurs.

FIG. 12 is an explanatory view illustrating an example of transferring an unexposed wafer when an abnormality occurs.

FIG. 13 is an explanatory view illustrating an example of transferring an unexposed wafer when an abnormality is resolved.

FIG. 14 is a schematic plan view of a substrate processing apparatus according to a second embodiment.

FIG. 15 is a schematic plan view of a substrate processing apparatus according to a third embodiment.

### DETAILED DESCRIPTION

Reference will now be made in detail to various embodiments, examples of which are illustrated in the accompanying drawings. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components have not been described in detail so as not to unnecessarily obscure aspects of the various embodiments.

### [Overview of Transfer in Coating/Developing Apparatus]

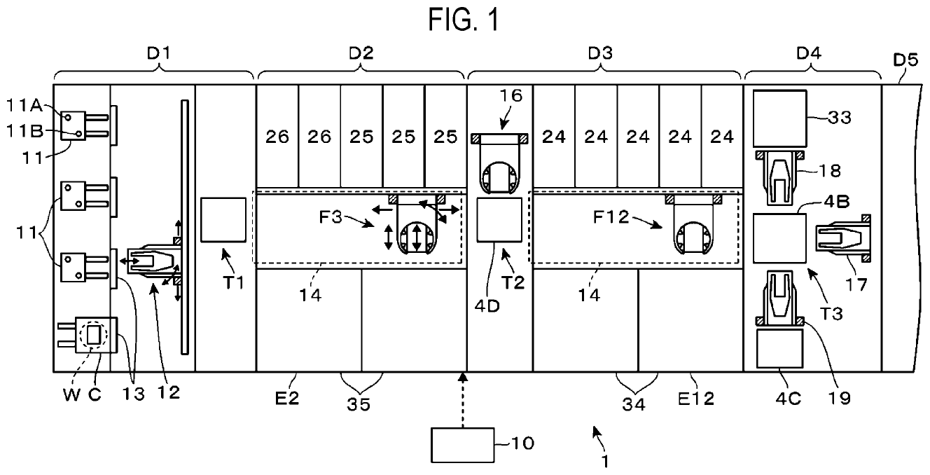

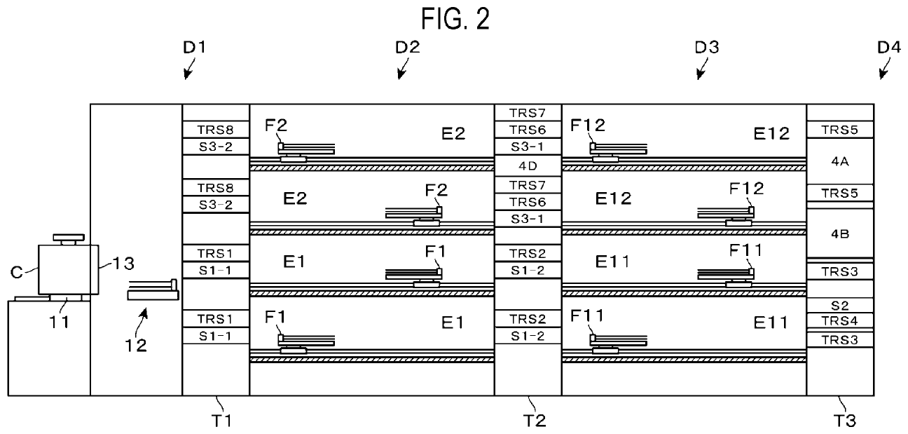

A plan view and a vertical cross-sectional front view of a coating/developing apparatus 1 in which a transfer method as an embodiment of a substrate transfer method of the present disclosure is implemented are illustrated in FIGS. 1 and 2, respectively. This coating/developing apparatus 1 is a first embodiment of a substrate processing apparatus including a substrate transfer apparatus, and includes a carrier block D1, a left processing block D2, a right processing block D3, and an interface block D4, which are connected in that order from left to right. An exposure machine D5 is connected to the right side of the interface block D4. Each of the carrier block D1, the left processing block D2, the right processing block D3, the interface block D4, and the exposure machine D5 has a housing, and the interior of each of the blocks and exposure machine is partitioned by the housing.

The coating/developing apparatus 1 is installed in a clean room of a semiconductor device manufacturing factory in an air atmosphere, and a carrier C in which a plurality of wafers W as substrates can be accommodated and individually placed is transferred by a transfer mechanism (not illustrated). The carrier C is, for example, a transfer container called a front opening unify pod (FOUP). A wafer W taken out from the carrier C is sequentially transferred through various modules provided in the coating/developing apparatus 1, processed, and returned to the carrier C. Therefore, the wafer W undergoes processing at various locations up to the carrier C. A module is a place other than a transfer mechanism where a wafer W is placed, and a module that processes a wafer W may be referred to as a processing module. This processing also includes temperature adjustment of a wafer W or image acquisition for inspection.

The processing performed in the coating/developing apparatus 1 includes forming a resist film on a wafer W by coating a metal-containing resist, heating after the resist film is exposed in the exposure machine D5 (post-exposure bake (PEB)), and developing the resist film. The PEB and development are performed twice, in which, in the first process, a pattern approximating a desired shape is formed on the resist film, and in the second process, the pattern is shaped into the desired shape.

More specifically, the above-mentioned metal-containing resist film is, for example, a metal oxide resist (MOR). This MOR is a negative resist for extreme ultraviolet (EUV) that contains, for example, tin (Sn) as a metal. The term “metal-containing” as used herein means containing a metal as a constituent component, but does not mean containing a metal as an impurity. Hereinafter, when the term “resist” is written, it is assumed that the resist means an MOR unless otherwise specified.

The MOR deteriorates by reacting with various components contained in the air after being applied to a wafer W. Due to this deterioration, there is a possibility that the shape of the resist pattern may not be a desired shape and a deviation of the line width (critical dimension (CD)) from the desired value may become large, or the hardness of the resist pattern may decrease. On the other hand, in a substrate processing apparatus that sequentially transfers and processes wafers W along a transfer path, an abnormality that temporarily prevents transfer to a scheduled transfer destination may occur, and the transfer may become stagnant in the upstream side of the location where the transfer becomes impossible. That is, when wafers W coated with the MOR are sequentially transferred in a substrate processing apparatus and subjected to post-coating process, there is a possibility that the stagnation of transfer may occur, causing deterioration of the resist film so that a CD or hardness abnormality may occur in the above-mentioned resist pattern.

There is a possibility that the above-mentioned abnormality due to the deterioration of the resist film may cause problems when a lower layer film formed under the resist film is etched by using the resist film as a mask to transfer the pattern to the lower layer film. Specifically, there is a possibility that an abnormality may also occur in the CD of the lower layer film pattern due to the deviation of the CD of the resist pattern, or a problem such as disappearance of the resist film during etching may occur due to a decrease in etching resistance due to a decrease in the hardness of the resist pattern. Due to such circumstances, it is required to suppress deterioration of a metal-containing resist film formed on a wafer W before pattern formation is completed. The coating/developing apparatus 1 is configured to meet such requirement.

An organotin oxide-based MOR reacts with components such as water in the air, acidic gases (carbon dioxide, hydrogen sulfide, nitrogen dioxide, nitric acid gas, and the like), hydrogen chloride, chlorine, sulfur dioxide, ammonia, amines, and organic substances and causes the above-mentioned deterioration. Therefore, in order to prevent the deterioration, it is particularly effective to place a wafer W coated with an MOR in an inert gas atmosphere so that the content of these components can be kept low. Therefore, some of the modules constituting the transfer path for a wafer W after formation of a resist film in the coating/developing apparatus 1 are configured such that the wafer W stays in a space where an atmosphere of nitrogen (N₂) gas, which is an inert gas, is formed, or the wafer W is processed in that space. These modules are provided with, for example, a housing that accommodates a wafer W, and a shutter that partitions the inside of the housing from the outside of the housing, such as a buffer module 4 to be described later, and is configured such that the inside of the housing is provided with a second atmosphere, which is a N₂ gas atmosphere.

However, it is difficult to configure some modules to form such an N₂ gas atmosphere. For example, in the case of a liquid processing module that performs processes such as coating a wafer W with a chemical liquid for film formation, cleaning with a cleaning liquid, and developing with a developer, since the volume of the space in which a wafer W is accommodated is relatively large, it is difficult to form such N₂ gas atmosphere. The volume is increased because the liquid processing module is provided with: a moving region for moving a nozzle, a brush, or the like for processing a wafer W with a liquid; a rotary mechanism that rotates the wafer W in order to widely distribute the supplied liquid to various locations of the wafer W, to shake the liquid off from the processed wafer W; and the like.

Therefore, the coating/developing apparatus 1 is provided with a buffer module that is capable of accommodating a large number of wafers W for evacuation thereof, and the inside of this buffer module is configured to have the N₂ gas atmosphere. When an abnormality that a wafer W, which stays in a module where the N₂ gas atmosphere is not formed after formation of a resist film, cannot be transferred to a scheduled destination module occurs, the wafer W is transferred to the buffer module instead of being transferred to that module. This prevents deterioration of the metal-containing resist film before the formation of the resist pattern is completed (before the above-mentioned shaping is completed). Further, when the transfer to the scheduled transfer destination is possible, the wafer W is not transferred to the buffer module. This is to prevent a decrease in throughput by suppressing the number of transfer operations (the number of transfers between modules) of the transfer mechanism.

Each module in which the N₂ gas atmosphere is formed, including the buffer module, is referred to as an atmosphere-controlled module. As described above, in the coating/developing apparatus 1, the transfer of a wafer W to the buffer module is performed when necessary, thereby suppressing variations among wafers W in the time during which the wafers W do not stay in an atmosphere-controlled module until the second development is completed after the formation of a resist film. This suppresses variations among wafers W in the shape or the like of resist patterns to be formed.

### [Configuration in Coating/Developing Apparatus]

Individual blocks (a carrier block, a left processing block, a right processing block, and an interface block) D1 to D4 of the coating/developing apparatus 1 will be specifically described below. These blocks D1 to D4 are each provided with a transfer mechanism within a housing, and the left processing block D2, the right processing block D3, and the interface block D4 are each provided with various modules within the housing.

### [Configuration of Carrier Block]

The carrier block D1 includes a plurality of stages 11 on which carriers C are placed outside the housing that constitutes the carrier block D1. The carrier block D1 includes a transfer mechanism 12, which accesses the carriers C on the stages 11 and carries wafers W into and out of the coating/developing apparatus 1. Each carrier C includes an opening connected to an accommodation space for wafers W on its side, and a lid for opening and closing this opening. When loading/unloading wafers W into/from the carrier C, a door 13 for opening and closing a substrate transfer port provided in a side wall of the housing of the carrier block D1 moves together with the lid of the carrier C which is in close contact with this side wall at the entrance edge of the opening. As a result, the lid is attached to and removed from the carrier C.

In addition, each stage 11 is provided with connectors 11A and 11B that are connected to the bottom surface of each carrier C. The accommodation space for wafers W inside the carrier C is a sealed space, but when the carrier C is placed on the stage 11, supply and exhaust of N₂ gas for the accommodation space may be performed via the connectors 11A and 11B, respectively, which makes it possible to form the N₂ gas atmosphere in the accommodation space. However, in the configuration example of the apparatus described with reference to FIGS. 1 and 2, no resist film is formed on a wafer W when the wafer W is carried out from the carrier C, and the development is completed at the time of loading the wafer W into the carrier C. Therefore, since the atmosphere within the carrier C has little influence on the resist, it is not necessary to form the N₂ gas atmosphere via the connectors 11A and 11B.

### [Configuration of Processing Block]

Next, the left processing block D2 and the right processing block D3, which are processing blocks, will be described. The left processing block D2 has a total of four floors, with two floors E1 and two floors E2, in which liquid processing and heating are performed on wafers W and which are stacked in order from the bottom. In these floors, wafers W are transferred and processed in parallel. The two floors E1 are configured similarly to each other, and the two floors E2 are configured similarly to each other.

The floor E2 illustrated in FIG. 1 will be described. A wafer transfer path 14 extending in the left and right direction is provided in the center of the front and back direction of the floor E2. In front of the transfer path 14, developing modules 35, which are liquid processing modules, are arranged side by side in the left and right direction, and perform second development. At the rear of the transfer path 14, heating modules for heating wafers W are stacked, and a large number of stacked heating modules are arranged side by side in the left and right direction. Each heating module includes a hot plate on which a wafer W is placed and heated. These heating modules include heating modules 25 that perform the second PEB, and post-development heating modules 26 that perform the post-second-development heating (post-bake). The transfer path 14 is provided with a transfer mechanism F2 that transfers wafers W in the floor E2.

Regarding the floor E1, the layout of the liquid processing modules, the heating modules, the transfer path 14, and the transfer mechanism is the same as that of floor E2, and an antireflection film forming module 31 which supplies a chemical liquid to a wafer W to form an antireflection film is provided as a liquid processing module. As heating modules, a heating module 22 which heats a wafer W after formation of an antireflection film, and a hydrophobizing module 21 which supplies a processing gas to the front surface of a wafer W to make the front surface hydrophobic during heating are provided. A transfer mechanism corresponding to the transfer mechanism F2 in the floor E1 is referred to as a transfer mechanism F1.

On the left side of the transfer paths 14 of the floors E1 and E2, a tower T1 in which a large number of modules are stacked is provided so as to penetrate through each floor. Each module of the tower T1 is accessible by the transfer mechanism 12 and a transfer mechanism in the floor located at the same height as the module among the transfer mechanisms F1 and F2.

Except that the types of modules installed therein are different from the modules in the left processing block D2, the right processing block D3 has the same configuration as the left processing block D2, and the floors corresponding to the floors E1 and E2 are indicated as E11 and E12, respectively. The difference between the floors E12 and the floors E2 is that developing modules 34 are provided side by side in the left and right direction as liquid processing modules and perform first development. As heating modules, heating modules 24 that perform the first PEB are provided. A transfer mechanism corresponding to transfer mechanism F2 is illustrated as F12.

The difference between the floor E11 and the floor E1 is that a resist film forming module 32, which forms a resist film by applying the above-mentioned MOR, is provided as a liquid processing module. As a heating module, a heating module 22, which performs heating after formation of a resist film called a pre-applied bake (PAB), is provided. A transfer mechanism corresponding to the transfer mechanism F1 is illustrated as F11. In addition, except that the chemical liquids supplied to wafers W are different, the resist film forming module 32, the antireflection film forming module 31, and the developing modules 34 and 35 have generally the same configuration, and the above-mentioned cup, nozzle, and rotary mechanism for wafers W are provided. In the resist film forming module 32 and the antireflection film forming module 31, a solvent is supplied to a rear surface and a peripheral edge of wafer W to remove unnecessary films formed on these portions.

The tower in the right processing block D3 corresponding to the tower T1 is illustrated as T2, and a transfer mechanism 16, which is a transfer mechanism that can be raised and lowered across the floors, is provided behind this tower T2. Each module of the tower T2 is accessible by the transfer mechanism 16 and a transfer mechanism in the floor located at the same height as the module among the transfer mechanisms F1, F2, F11, and F12. As the modules constituting this tower T2, a buffer module 4D is included. This buffer module 4D and buffer modules 4A to 4C, which will be described later, are modules that accommodate a plurality of wafers W in the N₂ gas atmosphere as described above, and accommodate wafers W at different stages of the transfer paths, respectively, which will be described later in detail.

In addition, a base that is movable on the transfer path 14, and two holders that are provided on the base and are movable forward and backward independently of each other when holding wafers W, are provided for the transfer mechanisms F1, F2, F11, and F12. In addition, these transfer mechanisms F1, F2, F11, and F12 sequentially and repeatedly move between the modules, and perform replacement of the wafers W for each module except for the entrance module and exit module of the section in which each of the transfer mechanisms is in charge of transferring the wafer. Therefore, these transfer mechanisms F1, F2, F11, and F12 circulatingly move along the transfer path 14, and perform replacement transfer in which the wafers W are sequentially transferred one by one from the upstream module to the downstream module on the transfer path.

### [Configuration of Interface Block]

Subsequently, the interface block D4 will be described. The interface block D4 includes buffer modules 4A to 4C. In addition, the interface block D4 is provided with a tower T3, transfer mechanisms 17 to 19, and a rear surface cleaning module 33. Like the towers T1 and T2, the tower T3 is configured by stacking a large number of modules, includes buffer modules 4A and 4B, and is provided on the right side of the transfer path 14 of the right processing block D3.

The transfer mechanism 17 is provided on the right side of the tower T3, and the transfer mechanisms 18 and 19 are provided on the rear and front sides of the tower T3, respectively. Behind the transfer mechanism 18, a plurality of (e.g., four) rear surface cleaning modules 33, which are liquid processing modules, are provided in a stacked manner. Each rear surface cleaning module 33 includes the above-mentioned cup, brush, nozzle, and rotary mechanism. Cleaning is performed on the rear surface of a wafer W accommodated in the cup by supply of a cleaning liquid from the nozzle and slide movement of the brush. In addition, since the number of wafers W that can be accommodated in one rear surface cleaning module 33 is one, a total of four wafers W can be accommodated in a total of four rear surface cleaning modules 33 at maximum. A buffer module 4C is provided in front of the transfer mechanism 18.

Each of the transfer mechanisms 17 to 19 can be raised and lowered to deliver wafers W to the tower T3. The transfer mechanism 17 delivers wafers W between the tower T3 and the exposure machine D5. The transfer mechanism 18 delivers wafers W between each module of the tower T3 and the rear surface cleaning module 33, and the transfer mechanism 19 delivers wafers W between each module of the tower T3 and the buffer module 4C.

The towers T1, T2, and T3 each include a delivery module TRS in which a wafer W is temporarily placed for delivery between modules, and a temperature adjusting module. In the following description, a delivery module TRS may be simply described as a TRS. The temperature adjusting module includes a stage on which a wafer W is placed, and this stage is provided with a flow path through which cooling water flows by a chiller. The wafer W placed on the stage is cooled by heat exchange with the stage, and the temperature of the wafer W is adjusted to a predetermined temperature.

The above-mentioned temperature adjusting modules are distinguished from each other by assigning reference numeral S1 to a temperature adjusting module on which a wafer W is placed before resist film formation, reference numeral S2 to a temperature adjusting module on which a wafer W is placed immediately before being transferred to the exposure machine D5, and reference numeral S3 to a temperature adjusting module on which a wafer W is placed after being carried into the exposure machine D5. Therefore, a wafer W transferred from the temperature adjusting module S2 is transferred to the exposure machine D5 without passing through any other module. This temperature adjusting module S2 may be referred to as a pre-exposure temperature adjusting module. The wafer W immediately before being transferred to the exposure machine D5 means a wafer W in a module immediately before the exposure machine D5 on the transfer path, which is directly transferred to the exposure machine D5 without being transferred to any other module other than that module.

The pre-exposure temperature adjusting module S2 is provided in the tower T3, and the temperature adjusting modules S1 and S3 are provided in the towers T1 and T2. In addition, the delivery modules TRS and the temperature adjusting modules S1 and S3 may be indicated by adding other numbers so as to be distinguished from each other, depending on the order in which wafers W are transferred. Although a large number of delivery modules TRS and temperature adjusting modules S1 to S3 having the same transfer path are provided, only one or two are illustrated in FIG. 2 for convenience of illustration. For example, three temperature adjusting modules S2 are provided, each of which is capable of accommodating one wafer W, but only one is illustrated in FIG. 2.

Among the modules described above, the buffer modules 4A to 4D, the pre-exposure temperature adjusting modules S2 and S3, and the heating modules 24 and 25 for PEB are the above-mentioned atmosphere-controlled modules, and the N₂ gas atmosphere, which is the second atmosphere, is provided inside the modules. A wafer W in a period from a time at which it is carried out from a carrier C to a time at which it is returned to the carrier C, is exposed to the air atmosphere, which is the first atmosphere, at a time other than the time during which the wafer W is staying in these modules. In addition, since an air atmosphere, which is the first atmosphere, is formed in the modules other than the atmosphere-controlled modules to which a wafer W after completion of formation of a resist film and before transfer to the developing module 35 for the second development is transferred, the reaction of the resist film is promoted compared to the atmosphere-controlled modules. Specifically, the rear surface cleaning module 33, the developing module 34, and the like are modules that provide an atmosphere in which the reaction of the resist film is promoted.

### [Regarding Buffer Module]

In the buffer modules 4A to 4D, the buffer module 4A accommodates a wafer W after formation of a resist film and before transfer to the rear surface cleaning module 33. The buffer module 4B accommodates a wafer W after being processed in the rear surface cleaning module 33 and before being transferred to the temperature adjusting module S2. The buffer module 4C accommodates a wafer W after being exposed by the exposure machine D5 and before being subjected to the initial PEB. The buffer module 4D accommodates a wafer W after being subjected to the first development and before being subjected to the second PEB. Hereinafter, the buffer modules 4A, 4B, 4C, and 4D may be referred to as a pre-cleaning buffer module, a pre-exposure buffer module, a post-exposure buffer module, and a post-first-development buffer module, respectively. Transfer to the buffer modules 4B to 4D among these modules is not performed if unnecessary.

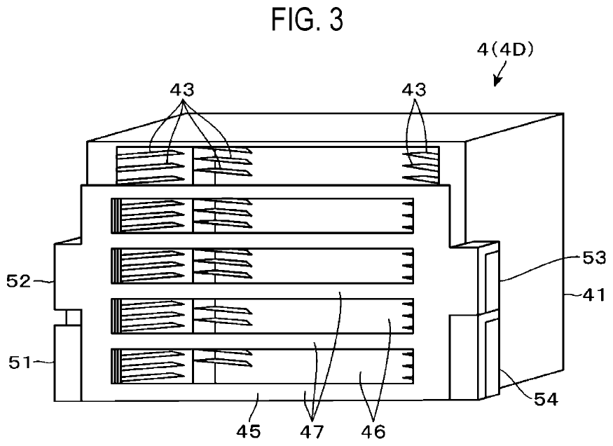

The configurations of buffer modules 4A to 4D are the same. As a representative example, the configuration of the buffer module 4D will be described with reference to the perspective views of FIGS. 3 to 5. The buffer module 4D includes a rectangular housing 41 and has a configuration in which one of the four side walls has been removed. The side where the side wall is removed and opened in this way will be referred to as the front side of the housing 41.

The inside of the housing 41 is configured as a wafer accommodation region 42. On the side walls of the housing 41, supports 43 that support wafers W are provided in multiple stages, in which the supports 43 extend from each of the four corners of the accommodation region 42, which is rectangular in a plan view, toward the center of the accommodation region 42. Four supports 43 located at the same height form a set to support the peripheral edge of the rear surface of one wafer W so as to place the wafer W on standby in a horizontal position. When the wafer standby regions formed by the same set of supports 43 in this way is called a slot, a large number of (e.g., 18) slots are provided, and respective slots may be numbered and referred to as Slot 1, Slot 2, Slot 3, and so on. A gas supply 44 is provided at the back side of the housing 41 to supply N₂ gas forward inside the housing 41, so that the respective wafers W in Slots 1 to 18 are exposed to the flow of the N₂ gas.

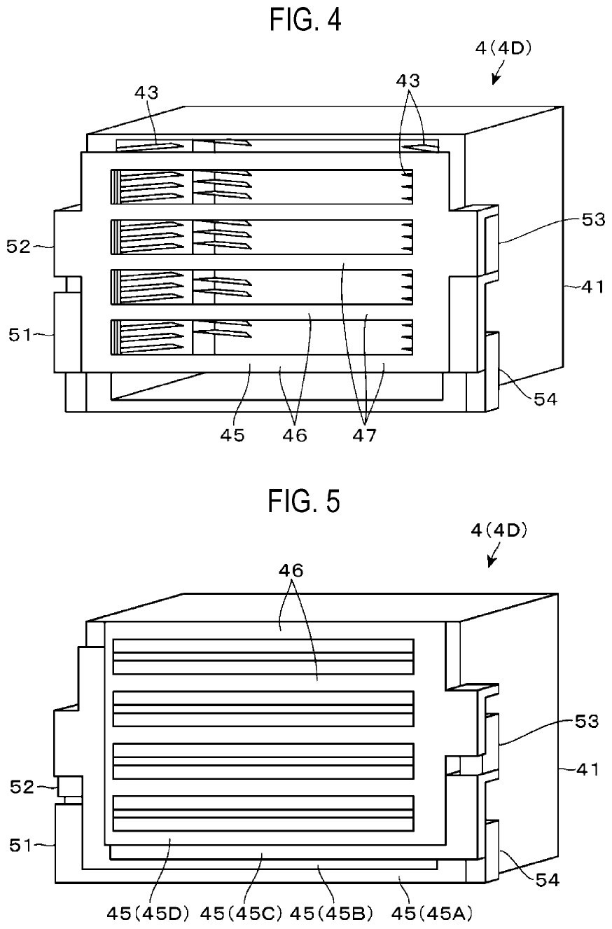

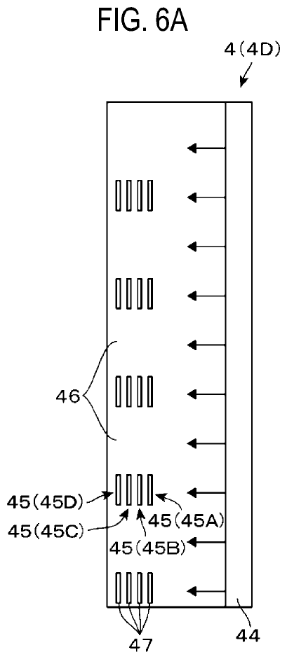

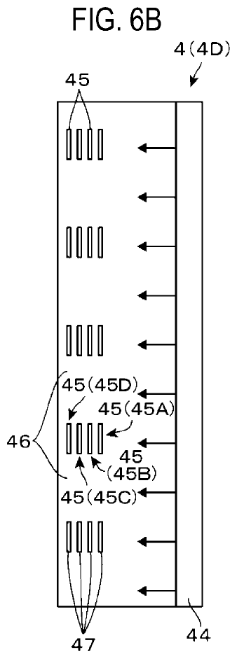

Four shutters 45 are provided on the front side of the housing 41. The respective positions of these four shutters 45 from the front side to the back side are different from each other. Each of the shutters 45 may be raised and lowered, and may be switched between the state in which some of the slots are open to the transfer region outside the housing 41 (the state illustrated in FIGS. 3 and 4) and the state in which all of the slots are partitioned from the outside of the housing 41 (the state illustrated in FIG. 5). The slots that are open to the outside may be changed. Referring to the configuration of the shutters 45 in detail, the four shutters 45 are configured similarly to each other, and each includes four horizontally elongated through holes 46 which are arranged vertically. By including the four through holes 46 in this way, when viewed from the front to the back, it can be seen that five bridge portions 47, which interconnect the left and right ends horizontally, are provided in each shutter 45 in the vertical direction. FIGS. 6A to 6C schematically illustrate heights of the bridge portions 47 when each shutter 45 is raised and lowered, in which FIGS. 6A to 6C illustrate the positions of the bridge portions 47 in the states of FIGS. 3 to 5, respectively. In addition, the arrows in FIGS. 6A to 6C indicate the flow of the above-mentioned N₂ gas.

For convenience of description, the four shutters 45 will be referred to as shutters 45A to 45D. Lifting mechanisms 51 to 54 are provided on the front side of the housing 41. When viewed from the front to the back, the lifting mechanisms 51 and 52 are provided on the left side of the housing 41, and the lifting mechanisms 53 and 54 are provided on the right side of the housing 41. The lifting mechanism 51 is connected to the shutter 45A and the lifting mechanism 52 to be capable of raising and lowering the shutter 45A and the lifting mechanism 52, and the lifting mechanism 52 is connected to the shutter 45B to be capable of raising and lowering the shutter 45B. By being connected to the lifting mechanism 51 via the lifting mechanism 52, the shutter 45B is also raised and lowered by the lifting mechanism 51. The lifting mechanism 53 is connected to the shutter 45C and the lifting mechanism 54 to be capable of raising and lowering the shutter 45C and the lifting mechanism 54, and the lifting mechanism 54 is connected to the shutter 45D. Therefore, the shutters 45C and 45D are raised and lowered by the lifting mechanism 53. By being connected to the lifting mechanism 53 via the lifting mechanism 54, the shutter 45D is also raised and lowered by the lifting mechanism 53. With the above configuration, the shutters 45A to 45D can be raised and lowered relative to each other.

The lifting mechanisms 51 to 54 are configured with, for example, cylinders, and can move the shutters 45 connected thereto between a raised position and a lowered position. As described above, the lifting mechanisms 51 and 53 also move the lifting mechanisms 52 and 54 together with the shutters 45, in which the moving distance of the shutters 45 and the moving distance of the lifting mechanisms 52 and 54 are the same. Further, in the lifting mechanisms 51 to 54, the distances between the raised positions and the lowered positions of the shutters 45 connected thereto are the same. Regarding each of the lifting mechanisms 51 to 54, assuming that a state in which the shutter 45 connected thereto is located at the raised position is referred to as an UP state, and a state in which the shutter 45 is located at the lowered position is referred to as a DOWN state, all of the lifting mechanisms 51 to 54 are in the DOWN states in the buffer module 4D illustrated in FIG. 3 and FIG. 6A. In this state, the four through holes 46 in the shutters 45A to 45D overlap each other, and Slots 1, 2, 5, 6, 9, 10, 13, 14, 17, and 18 are open to the wafer transfer region outside the housing 41, so that wafers W can be transferred to/from these slots.

In addition, regarding the buffer module 4D illustrated in FIG. 4 and in FIG. 6B, the lifting mechanisms 51 and 53 are in the UP state, and the lifting mechanisms 52 and 54 are in the DOWN state. In this state, Slots 3, 4, 7, 8, 11, 12, 15, and 16 are open to the wafer transfer region outside the housing 41 so that wafers W can be transferred to/from these slots. Therefore, each of the slots 1 to 18 is set to one of the states illustrated in FIGS. 3 and 4 so that wafers W can be transferred. In addition, regarding the state illustrated in FIG. 4 and FIG. 6B, the four through holes 46 of the shutters 45A to 45D overlap each other as in the state illustrated in FIG. 3 and FIG. 6A, but the shutters 45A to 45D have different heights relative to the housing 41. In addition, regarding the buffer module 4D illustrated in FIG. 5 and FIG. 6C, the lifting mechanisms 51 are in the DOWN state, and the lifting mechanisms 52 to 54 are in the UP state. In this state, since the heights of the bridge portions 47 of the shutters 45 deviate from one another, the accommodation region 42 is partitioned from the outside of the housing 41. That is, Slots 1 to 18 are closed with respect to the outside of the housing 41.

In this manner, in the buffer module 4D, each shutter 45 is raised and lowered such that only a limited number of slots are open to the outside of the housing 41 in transferring the wafers W. Therefore, the concentration of N₂ gas in the housing 41 becomes relatively high, and deterioration of the resist film can be suppressed more reliably.

Further, as illustrated in FIG. 1, the coating/developing apparatus 1 includes a controller 10. The controller 10 is configured with a computer and has a program. A group of steps are incorporated in the program such that a series of transfers and processes in the coating/developing apparatus 1, to be described later, can be performed, and the controller 10 outputs control signals to each component of the film forming apparatus 1 by the program to control the operation of each component. Specifically, the operation performed by each transfer mechanism and operations for processing wafers W in the processing modules are controlled by the control signals. In addition, the controller 10 detects whether an abnormality occurs as a cause of stagnation of transfer, which will be described later. This detection operation includes determining whether a wafer W can be transferred from a transfer source to a transfer destination. The control on the operation of the above-described transfer mechanism includes control on the operation of the transfer mechanisms 12, 16 to 19, F1, F2, F11, and F12, which is performed based on a detection result of the presence or absence of an abnormality. A specific example thereof will be described later. The above-mentioned program is stored in a non-transitory computer-readable storage medium such as a compact disk, a hard disk, a memory card, or a DVD, and is installed in the controller 10.

### [Transfer Path in Coating/Developing Apparatus]

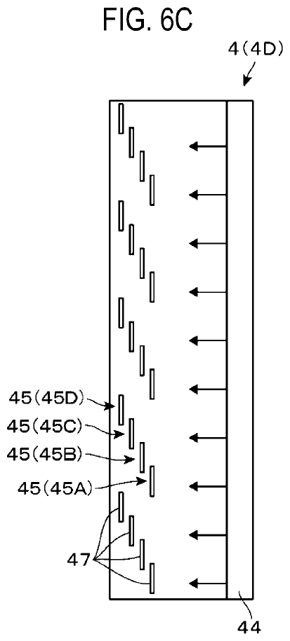

A wafer transfer path in the coating/developing apparatus 1 will be described with reference to FIGS. 7A to 7C. In FIGS. 7A to 7C, the wafer transfer path is indicated by solid line arrows connecting the modules, and transfer mechanisms used for inter-module transfer are illustrated near the arrows. In addition, the atmosphere-controlled modules in which the above-mentioned N₂ gas atmosphere is formed are indicated with a large number of dots in FIGS. 7A to 7C to distinguish the modules from the modules in which the wafer W is exposed to an air atmosphere.

A wafer W is carried out from a carrier C on a stage 11 by the transfer mechanism 12, and is transferred to a TRS 1 of the tower T1 in the left processing block D2. Of the two floors E1, the transfer mechanism F1 in the floor at the height of the TRS 1 to which the wafer W has been transferred receives the wafer W. Thereafter, the wafer W is transferred in the order of the hydrophobizing module 21, a temperature adjusting module S1-1 of the tower T1, the antireflection film forming module 31, the heating module 22, and a TRS 2 of the tower T2 in the right processing block D3. As a result, hydrophobizing, formation of an antireflection film, and heating are performed on the wafer W in that order.

Subsequently, the wafer W is transferred by the transfer mechanism 16 to a temperature adjusting module S1-2 of the tower T2. Of the two floors E11, the transfer mechanism F11 at the floor corresponding to S1-2 to which the wafer W has been transferred receives the wafer W, and the wafer W is transferred in the order of the resist film forming module 32, the heating module 23, and a TRS 3 of the tower T3 of the interface block D4. As a result, for the wafer W, the formation of a resist film and PAB are performed in this order.

Thereafter, the wafer W is transferred by the transfer mechanism 18 in the order of the pre-cleaning buffer module 4A, the rear surface cleaning module 33, and the pre-exposure temperature adjusting module S2, and is then transferred by the transfer mechanism 17 to the exposure machine D5. As a result, the wafer W is exposed to light in the state in which the rear surface has been cleaned and the temperature has been adjusted. In addition, due to the occurrence of an abnormality, the wafer W may be transferred from the rear surface cleaning module 33 to the pre-exposure temperature adjusting module S2 via the pre-exposure buffer module 4B instead of being directly transferred from the rear surface cleaning module 33 to the pre-exposure temperature adjusting module S2.

The wafer W exposed in this way is transferred to a TRS 4 of the tower T3 by the transfer mechanism 17, and is then transferred to a TRS 5 by the transfer mechanism 18. Further, of the two floors E12, the wafer W is received by the transfer mechanism F12 at the floor at the height corresponding to the TRS 5 to which the wafer W has been transferred, and is introduced into the right processing block D3. Due to the occurrence of an abnormality, the wafer W may be transferred from the TRS 4 to the TRS 5 via the post-exposure buffer module 4C instead of being transferred directly from the TRS 4 to the TRS 5. Further, the wafer W is transferred in the order of the heating module 24, the temperature adjusting module S3-1, the developing module 34, and a TRS 6 of the tower T2, and the first PEB, the temperature adjustment, and the first development are performed on the wafer W in that order so that a pattern is then formed on the resist film.

Further, the wafer W is transferred from the TRS 6 to a TRS 7 by the transfer mechanism 16. Due to the occurrence of an abnormality, the wafer W may be transferred to the TRS 7 from the TRS 6 via the post-first-development buffer module 4D after the first development instead of being transferred directly from the TRS 6 to the TRS 7. Of the two floors E2, the transfer mechanism F2 of the floor E2 at the height corresponding to the TRS 7 to which the wafer W has been transferred receives the wafer W, and the wafer W is introduced into the left processing block D2. Subsequently, the wafer W is transferred in the order of the heating module 25, the temperature adjusting module S3-2, the developing module 35, and a TRS 8 of the tower T1, and the second PEB, the temperature adjustment, the second development, and the post-development heating are performed in that order to shape the resist pattern. Further, the wafer W is returned to the carrier C by the transfer mechanism 12.

Wafers W are transferred along the above-described transfer path to the subsequent modules such that the order in which the wafers are carried out from the carriers C is maintained. Unloading from the carriers C is performed for each lot of wafers W. In the following description, wafers W belonging to any one lot may be expressed as A1, A2, A3, and the like according to the order of unloading from a carrier C. The wafers W of the same lot are processed in the same processing modules under the same processing conditions. The heating modules 23 to 25, the rear surface cleaning module 33, the developing modules 34 and 35, and the temperature adjusting modules S2 and S3, which are processing modules after formation of a resist film, correspond to a processing section. The heating modules 24 and 25 correspond to a first post-exposure heating module and a second post-exposure heating module, respectively, and the developing modules 34 and 35 correspond to a first developing module and a second developing module, respectively.

### [Examples of Abnormality Causes of Transfer Stagnation]

As described above, there are cases where transfer to a scheduled destination becomes temporarily impossible, and transfer along the above-mentioned transfer path is stagnant. Examples of causes for this include a case where transfer of a wafer W to the exposure machine D5 becomes temporarily impossible, a case where a transfer mechanism temporarily malfunctions, a case where transfer to all of the modules at the same stage in the transfer path becomes temporarily impossible, and the like. Specifically, the case where transfer to all of the modules at the same stage is impossible, is a case where, for example, provided that four developing modules 35 exist, transfer cannot be performed since all four developing modules 35 are unusable when transferring the wafer W from a temperature adjusting module S2-2, which is a transfer source, to the developing modules 35.

### [Transfer of Unexposed Wafer in Interface Block]

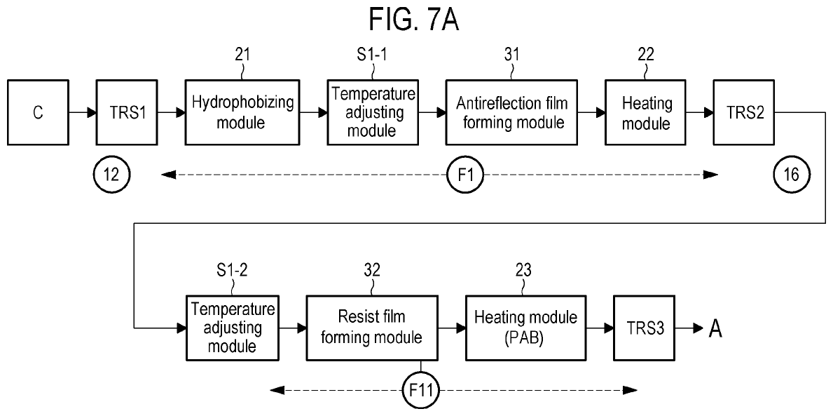

Next, transfer control of an unexposed wafer W in the interface block D4 will be described. In FIGS. 8 to 13, which will be referred to in the following description regarding transfer control, the atmosphere-controlled modules in which the N₂ gas atmosphere is formed are indicated with dots, as in FIGS. 7A to 7C.

When viewing the downstream side of the wafer transfer path from a rear surface cleaning module 33 in which an air atmosphere is formed, the nearest atmosphere-controlled module is a pre-exposure temperature adjusting module S2 (second placement part). However, let's suppose that it is impossible to transfer a wafer W to the pre-exposure temperature adjusting module S2. In this case, the wafer W is transferred from the rear surface cleaning module 33 (first placement part) in which the air atmosphere is formed to the buffer module 4B (standby chamber), and is put on standby. Further, when it becomes possible to transfer the wafer W to the pre-exposure temperature adjusting module S2, which is a second placement part, the wafer W is transferred from the buffer module 4B to the pre-exposure temperature adjusting module S2.

The above-mentioned transfer control will be described in more detail with reference to the drawings. FIG. 8 illustrates a state in which wafers W, which have been transferred normally on the previously described transfer path (i.e., there is no stagnation of transfer at various locations on the transfer path), become unable to be transferred to the exposure machine D5. This is the state in which an abnormality that transfer becomes impossible (stagnant) in the section of the transfer path after the pre-exposure temperature adjusting modules S2 is detected by the controller 10. Let's suppose that, at the time point at which transfer to the exposure machine D5 becomes impossible as described above, wafers A1 to A3 stay in three pre-exposure temperature adjusting modules S2, respectively, wafers A4 to A7 stay in the four rear surface cleaning modules 33, respectively, and a wafer A8 stays in the buffer module 4A. In addition, since the wafers W have been transferred normally before the abnormality occurs, there is no wafer W loaded in the pre-exposure buffer module 4B.

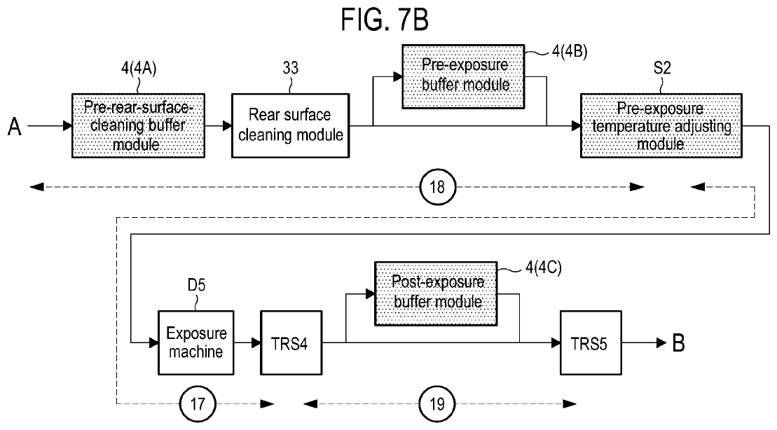

In such a case, each of the wafers W in the rear surface cleaning modules 33, in which the air atmosphere is formed, cannot be transferred to the pre-exposure temperature adjusting modules S2, in which the N₂ gas atmosphere is formed and which are the transfer destinations, because there is no vacant pre-exposure temperature adjusting module S2. When the wafers W are put on standby in the rear surface cleaning modules 33, respectively, the resist films will deteriorate. Therefore, wafers A4 to A7 in the rear surface cleaning modules 33 are transferred to the pre-exposure buffer module 4B by the transfer mechanism 18 in order of the processed wafers, and are put on standby in the N₂ gas atmosphere. Therefore, wafers are transferred to the pre-exposure buffer module 4B in numerical order starting from wafer A4, and FIG. 9 illustrates an example in which all wafers A4 to A7 of the rear surface cleaning modules 33 have been transferred to the pre-exposure buffer module 4B. On the other hand, wafer A8 in the pre-cleaning buffer module 4A in which the N₂ gas atmosphere is formed is not transferred to the rear surface cleaning module 33, but stands by in the pre-cleaning buffer module 4A.

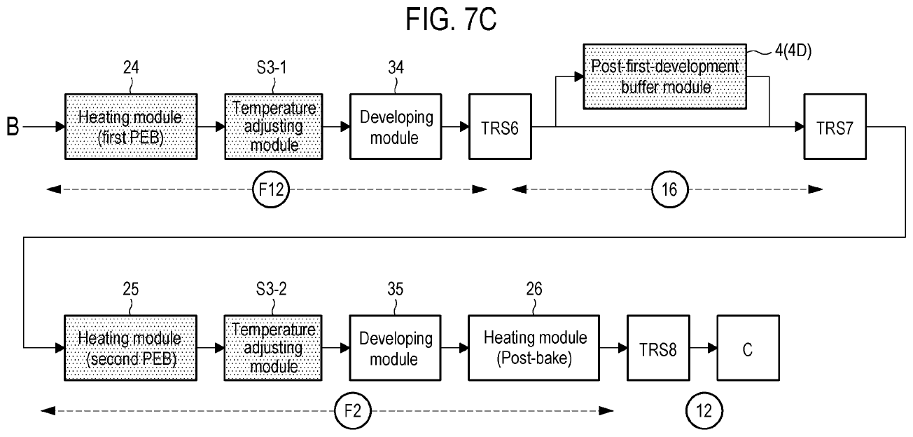

When transfer to the exposure machine D5 becomes possible in the state of FIG. 9, wafers A1 to A3 in the pre-exposure temperature adjusting modules S2 are transferred to the exposure machine D5 in numerical order by the transfer mechanism 17. As a result, since the pre-exposure temperature adjusting modules S2 become vacant (the state in which no wafers W are loaded), wafers A4 to A7 are sequentially transferred from the pre-exposure buffer module 4B to the vacant pre-exposure temperature adjusting modules S2 by the transfer mechanism 18. FIG. 10 illustrates a state in which a wafer A4 is transferred to a pre-exposure temperature adjusting module S2.

On the other hand, transfer of wafer A8 from the pre-cleaning buffer module 4A to the rear surface cleaning module 33 becomes possible, and the wafer A8 is transferred by the transfer mechanism 18 from the rear surface cleaning module 33 to a pre-exposure temperature adjusting module S2 without passing through the pre-exposure buffer module 4B. In addition, the transfer of the wafer A8 from the buffer module 4A may be performed after the transfer of wafers A4 to A7 from buffer module 4B is completed, or the transfer of the wafer A8 may be performed before the transfer of wafers A4 to A7 is completed. The subsequent wafers W after the wafer A8 are also transferred to the pre-exposure temperature adjusting modules S2 without passing through the pre-exposure buffer module 4B, similarly to wafer A8. The wafers W are loaded into the exposure machine D5 in numerical order of the wafers A1, A2, A3, A4, A5, A6, A7, A8, and so on.

In the case illustrated in FIG. 8, the transfer to the pre-exposure temperature adjusting modules S2 is not possible because there is no vacant pre-exposure temperature adjusting module S2. However, when a pre-exposure temperature adjusting module S2 is vacant, the wafer W in the rear surface cleaning modules 33 is transferred to the pre-exposure temperature adjusting module S2. Let's suppose a state similar to the state described with FIG. 8, except that, when an abnormality occurs to make loading into the exposure machine D5 impossible, transfer of the wafer A1 to the exposure machine D5 is completed and transfer of the wafers A2 and A3 to two of the three pre-exposure temperature adjusting modules S2 is completed with one pre-exposure temperature adjusting module S2 remaining vacant. In that case, the wafer A4 in the rear surface cleaning module 33 is transferred to the vacant pre-exposure temperature adjusting module S2. When the pre-exposure temperature adjusting module S2 is not vacant in the state in which the transfer to the exposure machine D5 is impossible, the wafers A5 to A7 are transferred to the pre-exposure buffer module 4B as illustrated in FIG. 9.

As described above, the control that transfer to the pre-exposure buffer module 4B is not performed as long as transfer to the pre-exposure temperature adjusting modules S2 is possible is to prevent an increase in the number of transfer operations of the transfer mechanism 18 that accesses the buffer module 4B. That is, in transferring the wafers W from the pre-exposure buffer module 4B after the abnormality is resolved, the number of transfer operations of the transfer mechanism 18 increases by the number of wafers W accommodated in the pre-exposure buffer module 4B. Thus, a transfer control is performed so that this increase in the number of operations is suppressed and a decrease in throughput is prevented.

The wafer A8 may be transferred to the rear surface cleaning module 33, which is the subsequent stage of the transfer path, but it is held in the pre-cleaning buffer module 4A as shown in FIGS. 8 and 9. This is because, when the wafer A8 is transferred to the rear surface cleaning module 33, it should be transferred to the pre-exposure buffer module 4B unless transfer to a pre-exposure temperature adjusting module S2 becomes possible. This increases the number of transfer operations of the transfer mechanism 18 as described above.

The number of pre-exposure buffer modules 4B to be installed is not limited to one, but a plurality of pre-exposure buffer modules can be provided, and the number of slots is also not limited to the above-mentioned number of eighteen. In addition, the number of rear surface cleaning modules 33 is also not limited to the above-mentioned number of four. However, as illustrated in FIG. 8, if wafers W stay in all of the rear surface cleaning modules 33 when an abnormality occurs, it is preferable that all of the wafers W can be transferred to the buffer modules 4B. Therefore, it is preferable that the total number of wafers W that can be accommodated in the buffer modules 4B be greater than or equal to the total number of wafers that can be accommodated in the rear surface cleaning modules 33. When only one buffer module 4B is provided, the number of slots in the one buffer module 4B is the total number of wafers that can be accommodated in the buffer module 4B, and when a plurality of buffer modules 4B are provided, the total number of slots in the plurality of buffer modules 4B are the total number of wafers that can be accommodated in the buffer modules 4B. The total number of wafers that can be accommodated in the rear surface cleaning modules 33 is the total number of the rear surface cleaning modules 33 because each rear surface cleaning module 33 accommodates one wafer W.

[Transfer of Wafer W Between Left and Right Processing Blocks after First Development]

Next, a case in which a wafer W for which a first development has been completed is transferred from the right processing block D3 to the left processing block D2 will be described. When the wafer W in a developing module 34 for first development in the right processing block D3 and a TRS 6 of the tower T2 cannot be transferred to the left processing block D2, the wafer W is transferred to the buffer module 4D for evacuation after first development. Specifically, the case where the wafer W cannot be transferred to the left processing block D2 is, for example, a case where transfer cannot be performed at any location in the section of the transfer path where the transfer mechanism F2 of the left processing block D2 is in charge of transferring the wafer. That is, a case where each transfer mechanism F2 of the left processing block D2 becomes temporarily inoperable, or a case where all of the processing modules on the same stage in the section of the transfer path where the transfer mechanism F2 is in charge of transferring the wafer become temporarily unusable and thus the wafer W cannot be transferred to a stage subsequent to the processing modules corresponds to the case where transfer of the wafer W to the left processing block D2 cannot be performed.

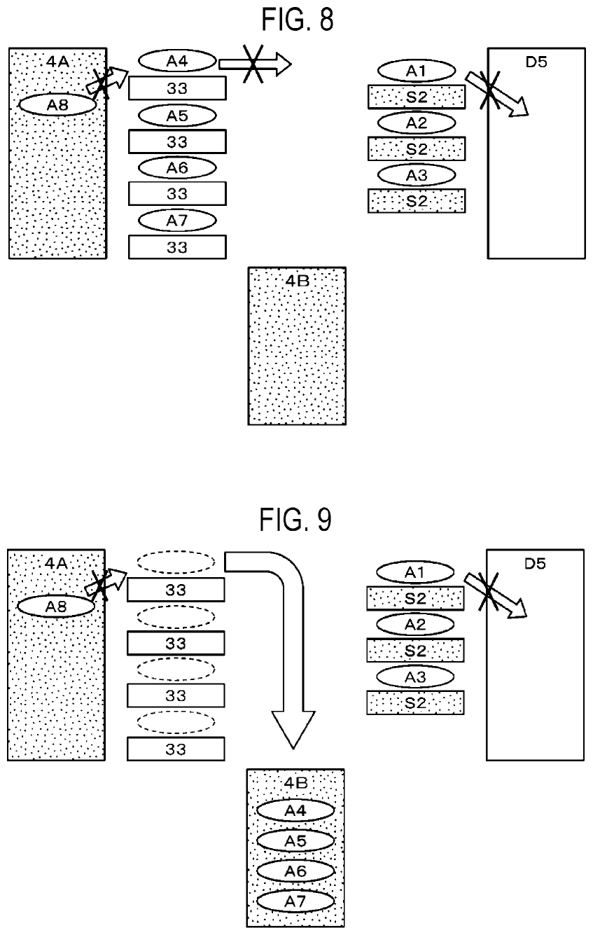

This will be described in detail with reference to FIGS. 11 to 13. As illustrated in FIGS. 1 and 2, in each of the right processing block D3 and the left processing block D2, the modules at each stage of the transfer path through which a wafer W after the first development passes are divided into two upper and lower floors, but FIGS. 11 to 13 depict the modules without dividing them into floors. In addition, the modules of the right processing block D3 are illustrated on the left, and the modules of the left processing block D2 are illustrated on the right. It is illustrated that there are two temperature adjusting modules S3-1 that adjust the temperature of a wafer W before the first development, four developing modules 34 for the first development, two TRSs 6 that serve as exits from the right processing block D3, and two TRSs 7 that serve as entrances of the left processing block D2.

FIG. 11 illustrates a state in which an abnormality that transferring the wafers W to the left processing block D2 is impossible is detected from a state in which the wafers W have been transferred normally on the previously described transfer path (i.e., there is no stagnation of transfer at various locations on the transfer path). Let's suppose that, at a time point at which such an abnormality is detected, wafers A1 and A2 stay in the two TRSs 6, respectively, wafers A3 to A6 stay in the four developing modules 34, respectively, and wafers A7 and A8 stay in the two temperature adjusting modules S3-1, respectively. In addition, since the wafers W are transferred normally before an abnormality occurs, the wafers W are not loaded into the post-first-development buffer module 4D.

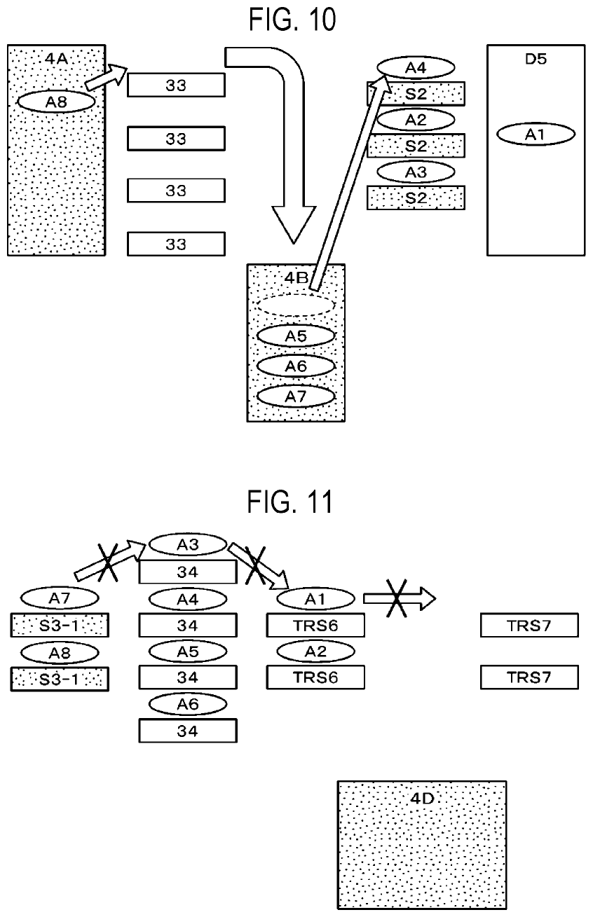

When the wafers W are put on standby in the developing modules 34 and the TRSs 6 in which the air atmosphere is formed, the resist films will deteriorate. Therefore, as illustrated in FIG. 12, the wafers A1 to A6 in the developing modules 34 and the TRSs 6, which are first placement parts, are sequentially transferred by the transfer mechanism 16 from the TRSs 6 to the post-first-development buffer module 4D, which is a standby chamber, and are put on standby. In this way, when the transfer becomes impossible in the section where the transfer mechanism F2, which circulatingly moves among modules, is in charge of transferring the wafer, the wafers W will not be transferred to the TRSs 7 at the entrance of that section. Further, in the section where the transfer mechanism F12 of the right processing block D3, which circulatingly moves among the modules, is in charge of transferring the wafer, the wafers W are transferred from the TRSs 6 at the exit of that section to the buffer module 4D for evacuation. That is, transfer is not performed between the section at the preceding stage where the circulatingly moving transfer mechanism F2 is in charge of transferring the wafer and the section at the subsequent stage where the circulatingly moving transfer mechanism F12 is in charge of transferring the wafer, and the wafers W are evacuated to the buffer module 4D from the section at the preceding stage. This prevents deterioration of the resist films. On the other hand, for wafers A7 and A8 in the temperature adjusting modules S3-1 in which the N₂ gas atmosphere is formed, transfer to the developing modules 34 is not performed, and wafers A7 and A8 are put on standby in the temperature adjusting modules S3-1.

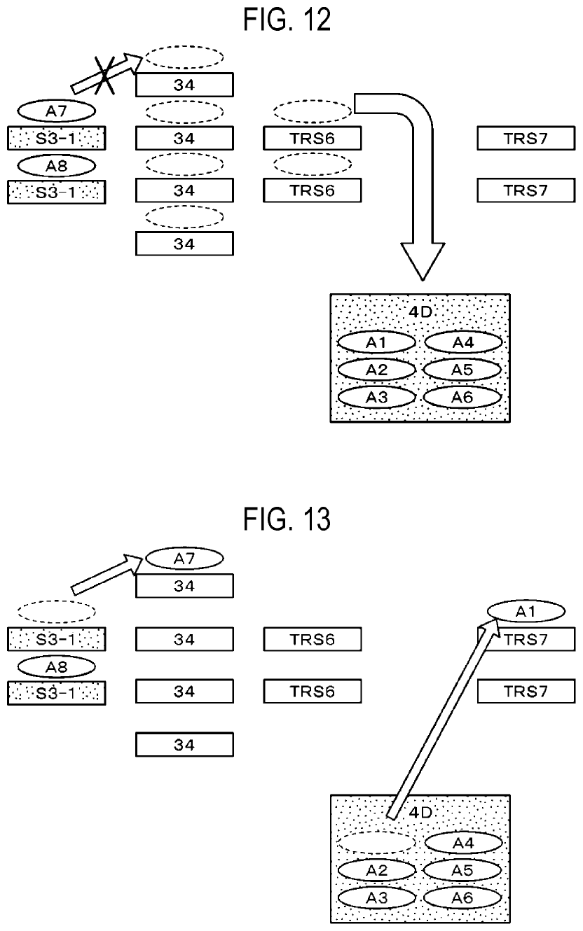

Further, when the transfer of the wafers W to the left processing block D2 becomes possible from the state illustrated in FIG. 12, the wafers A1 to A6 in the post-first-development buffer module 4D are sequentially transferred by the transfer mechanism 16 to TRSs 7 which are the second placement parts, as illustrated in FIG. 13. On the other hand, wafers A7 and A8 are sequentially transferred from the temperature adjusting modules S3-1 to the developing modules 34.

For the same reason as the reason that the wafers W in the pre-cleaning buffer module 4A are not transferred until an abnormality is resolved, as described above with reference to FIGS. 8 to 10, the wafers A7 and A8 are not transferred from the temperature adjusting modules S3-1 to the developing modules 34 while the transfer of the wafers W to the left processing block D2 is impossible. This prevents an increase in the number of wafers W accommodated in the buffer module 4D, which is caused when the wafers A7 and A8 are transferred to the buffer module 4D via the TRSs 6 after being transferred to the developing modules 34. As a result, the number of times the transfer mechanism 16 accesses the buffer module 4D after the abnormality is resolved is suppressed, thereby preventing a decrease in throughput.

As in the case of the pre-exposure buffer module 4B, it is preferable to set the number of post-first-development buffer modules 4D and the number of slots per module so that it is possible to accommodate the wafers W in a number greater than or equal to the total number of wafers W that can be accommodated in the modules which are the transfer sources. That is, since one wafer W is accommodated in each of the TRSs 6 and the developing modules 34, it is preferable that the post-first-development buffer modules 4D accommodate wafers W in a number greater than or equal to the total number of the wafers that can be accommodated in these modules. In addition, the number of buffer modules 4C and number of slots per module, which will be described later, are set in the same manner.

[Transfer of Wafer after Exposure and Before First Development]

A transfer control for the post-exposure buffer module 4C in the interface block D4 will be described. As described above with reference to FIGS. 11 to 13, it is determined whether to transfer the wafer W to the post-first-development buffer module 4D depending on whether the transfer of the wafer W after the first development to the left processing block D2 is possible. Similarly, whether to transfer the wafer W to the buffer module 4C may be determined depending on whether the transfer of a wafer W after exposure to the right side processing block D3 is possible. Specifically, when an abnormality that the transfer mechanism F12 of the right processing block D3 cannot perform transfer at any location in the section in which the transfer mechanism F12 of the right processing block D3 is in charge of transferring a wafer W is detected, the wafers W may be transferred by the transfer mechanism 19 from a TRS 4 (first placement part) to the post-exposure buffer module 4C (standby chamber). After the abnormality is resolved, the wafer W may be transferred by the transfer mechanism 19 from the post-exposure buffer module 4C to a TRS 5 (second placement part), which is the entrance of the section in which the transfer mechanism F12 is in charge of transferring the wafer.

### [Effect of Accommodating Wafer in Buffer Module]

According to the above-described coating/developing apparatus 1, when an abnormality is detected, the wafers W are transferred to the buffer modules 4B to 4D in which the N₂ gas atmosphere is formed and are put on standby, thereby preventing the wafers W from staying for a long period of time in the modules in which the air atmosphere is formed. As a result, deterioration of resist films due to the progress of various reactions is prevented, and variation in the CD of the resist patterns from designed values is suppressed. Therefore, when etching lower layer films using the resist films, deviation of the CD of the patterns formed in the lower layer films from the designed values is also suppressed. Further, since a decrease in hardness of the resist films is also suppressed, the disappearance of the resist films during the above-mentioned etching can also be prevented. Each of the transfer mechanisms 18, 19, and 16, which perform transfer to the buffer modules 4B, 4C, and 4D as described above, constitutes a substrate transfer apparatus together with the controller 10.

The effect of accommodating wafers W in the buffer modules 4C to 4D will be further described. Assuming that a series of transfer and processes are performed on the wafers W illustrated in FIGS. 7A to 7C in an air atmosphere, the time from resist film formation to exposure (PCD time), the time from exposure to PEB (PED time), and/or the time from PEB to development (PPD time) affects the deterioration of the resist films. PCD, PED, and PPD are abbreviations for post-coating delay, post-exposure delay, and post-PEB delay, respectively.

Further, when necessary, the wafers W are transferred to the pre-exposure buffer module 4B in which the N₂ gas atmosphere is formed, as described above, and are put on standby. By accommodating the wafers in the buffer module 4B, even if the above-mentioned PCD time varies among wafers W, since the wafers W are put on standby in the N₂ gas atmosphere, the influence on the resist film by variations in the PCD time is canceled.

In addition, by putting the wafers W on standby in each of the post-exposure buffer module 4C and the post-first-development buffer module 4D as necessary, during the normal operation of the transfer mechanisms F2 and F12, the wafers W can be transferred to the modules TRS 5 and TRS 7 that are the entrances of the sections where these transfer mechanisms are in charge of transferring the wafers. Since the transfer mechanisms F2 and F12 are in the normal operation state as described above, for each of the first PEB and development and the second PEB and development, the time for transferring the wafers from the heating module that performs the PEB to the developing module (i.e., the above-mentioned PPD time) is prevented from becoming abnormal. Further, by accommodating the wafers in the buffer modules 4C and 4D, even when variations in PED time occur among wafers W, the influence by the variations in PED time is canceled because the wafers are accommodated in the N₂ gas atmosphere.

As described above, the buffer modules at each stage are divided into those that suppress the influence of PCD time and those that suppress the influence of PED time and PPD time. Therefore, when the influence of any one of the PCD time, the PED time, and PPD time is small and the influence of the other is large, only the buffer module suitable for that time may be provided. In other words, when the influence of the PED time and the PPD time is large, only the buffer modules 4C and 4D may be provided without providing the buffer module 4B, and when the influence of the PCD time is large, only the buffer module 4B may be provided without providing the buffer modules 4C and 4D.

In addition, it is conceivable that depending on the types of used resist and developer, the deterioration of the resist film due to exposure to the air becomes less after the first development. In that case, when an abnormality that the transfer cannot be performed at any location in the section in which the transfer mechanism F12 of the right processing block D3 is in charge of transferring the wafers is detected, the wafer W may be transferred to the post-exposure buffer module 4C and is put on standby, as described above. On the other hand, even if an abnormality that the transfer cannot be performed at any location in the section in which the transfer mechanism F2 of the left processing block D2 is in charge of transferring the wafers is detected, the wafer W may be transferred from the TRS 6 to the TRS 7, without evacuating the wafers to the post-first-development buffer module 4D. That is, improvement of the throughput may be promoted by quickly transferring the wafer W to a module at a stage subsequent to the transfer path without performing the transfer control described above with reference to FIGS. 11 to 13.

### [Supplementary Information on Transfer Control for Each Buffer Module]

FIGS. 8 and 9 illustrate an example in which the wafers W in the rear surface cleaning modules 33 are transferred to the pre-exposure buffer module 4B when an abnormality that the transfer of the wafer from the pre-exposure temperature adjusting modules S2 to the exposure machine D5 is impossible is detected. However, the transfer to the buffer module 4B is not limited to being performed when the transfer of the wafers W to the exposure machine D5 becomes impossible. When the transfer becomes impossible in a section subsequent to the temperature adjusting modules S2 on the transfer path (the section subsequent to the pre-exposure buffer module 4B), there is a possibility that the wafers W in the rear surface cleaning modules 33 cannot be transferred to the temperature adjusting modules S2 due to the wafers staying at various locations. Therefore, even when a transfer abnormality is detected at a location other than the location between the pre-exposure temperature adjusting modules S2 and the exposure machine D5 in the section subsequent to the temperature adjusting modules S2, the wafers W in the rear surface cleaning modules 33 may be transferred to the pre-exposure buffer module 4B. For example, as illustrated in FIGS. 11 to 13, even when an abnormality that the transfer mechanism F2 cannot perform transfer of the wafers W occurs, the wafers W may be transferred to the pre-exposure buffer module 4B.

Supplementary explanation on the transfer to the buffer modules 4B to 4D is given below. As exemplified, wafers W staying in the modules having the air atmosphere therein in the upstream side of the buffer modules 4B to 4D are transferred to the buffer modules 4B to 4D, wherein the modules having the air atmosphere therein are positioned in the downstream of the modules having the N₂ atmosphere therein nearest to the buffer modules 4B to 4D. Therefore, the modules from which the wafers W are transferred to the buffer modules 4B to 4D when an abnormality is detected may be one type as in the example of FIG. 8, or may be two types as in the example of FIG. 11.

Let's suppose that the right processing block D3 of the coating/developing apparatus 1 is provided with an inspection module that takes an image to inspect the surfaces of the wafers W after the first development and before transfer to the TRSs 6 which serve as an exit of the right processing block D3, and the inspection module has an air atmosphere. That is, it is assumed that wafers W are transferred in the order of the developing modules 34, the inspection module, and the TRSs 6 instead of being transferred in the order of the developing modules 34 and the TRSs 6 as illustrated in FIG. 11. In this case, when an abnormality is detected, the wafers W are transferred from the developing modules 34, the inspection module, and the TRSs 6 (that is, from three types of modules) to the buffer module 4D.

### [Other Configuration and Operation of Coating/Developing Apparatus]

When an abnormality in the transfer path described above is detected, the transfer of the wafers W to the resist film forming module 32 may be stopped in parallel with the transfer of the wafers W to each buffer module 4. By doing so, it is possible to prevent the resist films from being formed on the wafers W after the occurrence of an abnormality, and from deteriorating due to continued stagnation of the transfer due to the continuation of the abnormality.

In order to stop the transfer of the wafers W to the resist film forming module 32 in this way, for example, the dispensing of the wafers W from the carrier C is stopped. Among the wafers W that have already been loaded into the coating/developing apparatus 1, each of the wafers W located in the modules (TRS 1 to S1-2) at a stage preceding the resist film forming module 32 on the transfer path may be put on standby in the module in which the wafer is currently located without being transferred to a module at a subsequent stage. Once the abnormality is resolved, the transfer of the wafers W from each module is resumed.

Although the layout of the interface block D4 has been exemplified, the layout is not limited to this, and the arrangement of each module and the number of transfer mechanisms may be changed as appropriate. Regarding the developing module, although an example has been illustrated in which development by a developer is performed, the first and/or second development may be performed by supply of the gas. In addition, the apparatus configuration is not limited to performing PEB and development twice, but may be an apparatus configuration in which PEB and development are performed only once, or an apparatus configuration in which development is performed three or more times.

Further, it has been described that the buffer module 4D is not limited to providing only one buffer module, but may be provided in plural numbers. As described above with reference to FIGS. 11 to 13, when there is no abnormality in each of the plurality of buffer modules 4D, the wafers W are transferred to, for example, each of the buffer modules 4D. When any of the buffer modules 4D (one buffer module) becomes abnormal, an operation may be changed such that the abnormal buffer module 4D is excluded and the wafers W are transferred only to each of the other buffer modules 4D (the other buffer module). Similarly to the buffer module 4D, regarding each of the buffer modules 4A to 4C, it is also possible to provide a plurality of buffer modules and to exclude the abnormal buffer module from use.

An operation may be used such that when a predetermined abnormality is detected in the coating/developing apparatus 1, the unloading of wafers W from the carrier C is stopped, and the wafers W that have already been loaded into the coating/developing apparatus 1 are transferred to the nearest buffer module 4 on the downstream side in the transfer path and are put on standby in the N₂ gas atmosphere. That is, the wafers W, which are respectively located in the TRSs 1 to 3 on the transfer path in FIGS. 7A to 7C, are transferred to the buffer module 4A when they reach the TRS 3. The wafers W in the rear surface cleaning modules 33 are transferred to the buffer module 4B as in the example illustrated in FIGS. 8 and 9. The wafers W, which are respectively located in the pre-exposure temperature adjusting modules S2 and the TRS 4, are transferred to the buffer module 4C upon reaching the TRS 4. When the wafers W, which are respectively located at TRSs 5 and 6, are transferred to the buffer module 4D upon reaching the TRS 6. The wafers W in the TRSs 7 and 8 at a stage subsequent to each buffer module 4 are transferred to the carrier C.

That is, all the wafers W on the upstream side of each of the buffer modules 4A to 4D are transferred to each of the buffer modules 4A to 4D. This transfer is called emergency evacuation transfer. By executing this emergency evacuation transfer, the wafers W are also transferred to the buffer modules 4C and 4D from modules other than a module which is a first placement part described with reference to FIG. 11 and the like. That is, the transfer sources for the buffer modules change depending on the type of an abnormality.

For example, the coating/developing apparatus 1 is configured to receive power from a main power supply, and to receive power from an emergency power supply when the power supply from the main power supply stops due to a power outage in the factory or the like. The predetermined abnormality that triggers the execution of the emergency evacuation transfer is, for example, the stoppage of power supply from the main power supply, and after the power supply from the main power supply is resumed, processing on each wafer W is continued by unloading the wafers W from each buffer module 4, and unloading of the wafers W from the carrier C is resumed. The controller 10 is configured to be able to detect the presence or absence of power supply from the main power supply, and perform a control such that the above-mentioned emergency evacuation transfer is executed based on the detection result. In addition, an example of the predetermined abnormality is a case where the transfer of the wafers W is stagnant at a plurality of locations on the above-described transfer path. More specifically, for example, when a case where the transfer to the exposure machine D5 described with reference to the drawings becomes impossible and a case where the transfer by the transfer mechanism F2 becomes impossible as described with reference to the drawings, occur simultaneously, the emergency evacuation transfer may be performed. Further, the emergency evacuation transfer is not limited to evacuating the wafers W to each of the buffer modules 4A to 4D, and the wafers W may be evacuated to any one of these buffer modules.

### [Atmosphere Formed in Atmosphere-Controlled Module]

Regarding the atmosphere-controlled module including the buffer module 4 (4A to 4D), it has been illustrated that an N₂ gas atmosphere is formed as an inert gas atmosphere, but an inert gas atmosphere other than N₂ gas, such as a rare gas such as helium, neon, argon, or xenon, may be formed. In addition, as described above, components such as water and CO₂ in the air may react with the resist film. The type of gas that reacts with the resist film varies depending on the composition of the resist film. Therefore, in the atmosphere-controlled module, the atmosphere formed to suppress the reaction of the resist film is not limited to the inert gas atmosphere.

Specifically, low-humidity air (dry air) may be supplied to an atmosphere-controlled module such as the buffer module 4 instead of an inert gas, and an atmosphere based on this air may be formed in the atmosphere-controlled module. More specifically, this low-humidity air is, for example, air with a humidity lower than the humidity of a clean room in which the coating/developing apparatus 1 is installed. For example, when the humidity of the air supplied into the carrier C is lower than the humidity obtained by randomly measuring the humidity ten times or more at different timings during the operation of the coating/developing apparatus 1, then the air corresponds to low-humidity air. The humidity in this specification is relative humidity unless otherwise specified. Instead of moisture, an atmosphere may be formed by supplying air with its components adjusted such that the concentration of CO₂ or acid gas of the air is lower than that in the air of the clean room.

Therefore, the atmosphere formed in the atmosphere-controlled module including the buffer module 4 is different from the atmosphere outside the atmosphere-controlled module. As a further explanation, the atmosphere that is formed in this atmosphere-controlled module and is different from the outside is not an atmosphere that is formed by chance, but is an atmosphere that is intentionally formed to suppress the reaction of the metal-containing resist, and is an atmosphere controlled such that specific components such as water and CO₂ are lower than the outside atmosphere. However, as described above, since the resist film reacts with various components, it is more preferable that the atmosphere formed in the atmosphere-controlled module be an inert gas atmosphere in order to suppress deterioration of the resist film.

[Variation of Coating/Developing Apparatus and Contact Time of Wafer with Air Atmosphere]

The coating/developing apparatus 1 is configured to perform only both the formation and development of the resist film as a processing block, but may be configured to perform only one of the formation and development, as in the substrate processing apparatuses 6 and 7 to be described later. That is, the processing block may include only one of the resist film forming module and the developing module. Therefore, a wafer W carried out from a carrier C may be returned to the carrier C without being developed after a resist film is formed. That is, a substrate processing apparatus may be configured as a coating apparatus. A wafer W on which a resist film has been exposed may be transferred from a carrier C to the apparatus, developed, and returned to the carrier C. That is, a substrate processing apparatus may be configured as a developing apparatus. In such a coating apparatus and a developing apparatus, an exposure device D5 may be connected via an interface block D4 in the same way as the coating/developing apparatus 1. When the interface block D4 is provided in this way, the transfer control described above with reference to FIGS. 8 to 10 may be performed.

On the other hand, as described above, in the coating/developing apparatus 1, transfer is performed such that variations in the time during which the wafers do not stay in the atmosphere-controlled module after the resist films are formed until the completion of development are suppressed among the wafers W, but it is preferable that the non-stay time be matched among the wafers. Explanations regarding this matching in time is supplemented. For example, among the wafers W that are unloaded from the same carrier C, let's suppose a difference of 60 seconds or less in the time during which the wafers W do not stay in the atmosphere-controlled module in the period between a time t1 at which the wafers are unloaded from the resist film forming module 32 and a time t2 at which the wafers are transferred to the developing module. This corresponds to a case where the time during which the wafers do not stay in the atmosphere-controlled module is matched among the wafers W.

In the case of the above-described coating apparatus, after formation of the resist film, the wafers W are returned to the carrier C in which the N₂ gas atmosphere can be formed by the stage 11 without being developed. For example, assuming that the difference in the time during which the wafers do not stay in the atmosphere-controlled module from the above-mentioned time t1 to the time at which the wafers are transferred to the carrier C is within 60 seconds among the wafers W unloaded from the same carrier C, this corresponds to the case where the time during which the wafers W do not stay in the atmosphere-controlled module is matched among the wafers.

In the case of the above-described developing apparatus, wafers W are unloaded from the carrier C in which the N₂ gas atmosphere is formed by the stage 11, toward the developing module. Assuming that, among the wafers W unloaded from the same carrier C, the difference in the time during which the wafers do not stay in the atmosphere-controlled module between the time at which the wafers are transferred from the carrier C and the time t2 at which the wafers are transferred to the developing module is, for example, within 60 seconds, this means that the time during which the wafers W do not stay in the atmosphere-controlled module is matched among the wafers W.

In addition, as described above, development may be performed only once or may be performed multiple times. In the coating/developing apparatus 1 and the developing apparatus, the time t2 at which the wafers W are transferred to the above-mentioned developing module is the time point at which the wafers are transferred to the developing module that performs the final development. In other words, when the wafers are transferred to the developing modules 34 and 35 as illustrated in the transfer path in FIGS. 7A to 7C, the time point at which the wafers W are transferred to the developing module 35 that performs the second development is the time point t2, and when the wafers are transferred only to the developing module 34, the time point at which the wafers W are transferred to the developing module 34 is the time point t2.

In the above-mentioned coating apparatus, after the wafers W are processed in the resist film forming module 32, the wafers W are returned to the carrier C via a TRS. When the wafers W cannot be transferred to this TRS, the wafers W may be evacuated to the buffer module 4 instead of being transferred to the TRS. That is, although the first placement part which serves as a transfer source of the wafers W for the buffer module 4 has been illustrated as a separate module from the resist film forming module 32 in each of the above-described examples, the resist film forming module 32 may be the first placement part. Therefore, the resist film forming module is the first placement part or a module at a stage subsequent to the first placement part. Even when the first placement part is the resist film forming module 32, the transfer of the wafers W to the resist film forming module 32 may be stopped when an abnormality occurs as described above.

In addition, although the substrate processing apparatus that performs formation and/or development of the resist film has been described, the present disclosure is not limited to such an apparatus configuration, and may be configured as an apparatus that performs processes other than the coating and development of the resist among respective processes of patterning the resist film. That is, the substrate processing apparatus may be an apparatus that performs only PAB or an apparatus that performs only rear surface cleaning. The above-described patterning corresponds to a series of processes after forming a resist film and before first etching a film (lower layer film) under the resist film. Therefore, the processes performed before first etching the first lower layer film, such as second and subsequent PEB and development when repeating PEB and development, post-development heating (post-bake), ultraviolet ray process for modifying the resist after development, or the like, correspond to the above-mentioned processes of patterning. There is a possibility that the deterioration of MOR may continue even after the second developer is supplied. Therefore, in the apparatus that performs the above-described post-bake or ultraviolet process, as described in the previous embodiments, deterioration of the resist films may be suppressed by evacuating the wafers W to the buffer module 4 depending on an abnormality in the transfer path.

[Standby Chamber Other than Buffer Module]

As described above, the carrier C on the stage 11 may have the N₂ gas atmosphere formed therein through the supply and exhaust of the gas by the stage 11. The carriers C in which the N₂ gas atmosphere is formed in this way may be used as a standby chamber. That is, instead of transferring the wafer W to a predetermined transfer destination when the abnormality is detected, the wafer W is transferred to the carrier C and put on standby. As a specific example, in the above-described developing apparatus, the transfer mechanism 12 takes out a wafer W on which a resist film has been formed from a carrier C and transfers the wafer W toward a TRS of the tower T1 of the processing block. If an abnormality is detected on the way to the TRS, the transfer mechanism 12 stops transferring the wafer W to the TRS, returns the wafer W to the carrier C, and puts the wafer on standby. That is, the carrier C is used as a standby chamber.

### [Configuration of Apparatus of Second Embodiment]

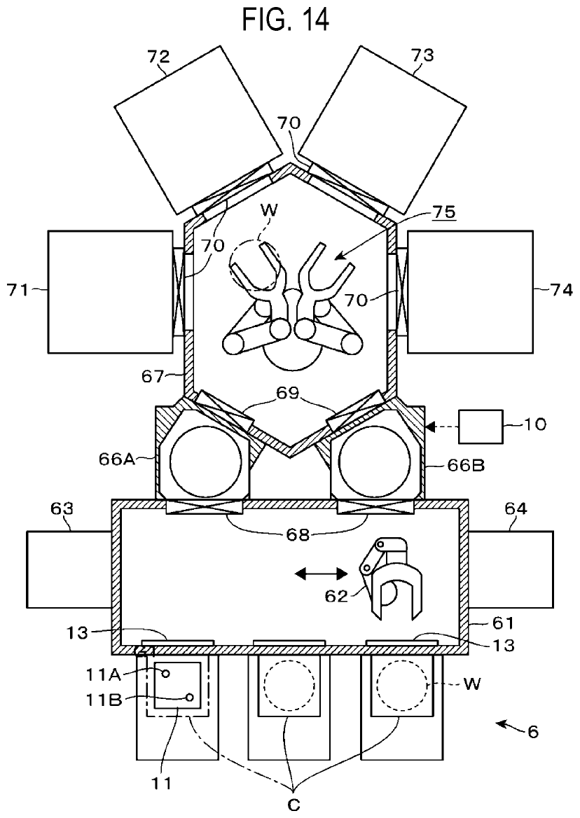

Next, a substrate processing apparatus 6 of a second embodiment will be described with reference to a plan view of FIG. 14, focusing on the differences from the coating/developing apparatus 1. The substrate processing apparatus 6 performs processing from resist film formation to PAB in a vacuum atmosphere. The substrate processing apparatus 6 includes a horizontally elongated normal pressure transfer chamber 61 in which a normal pressure atmosphere is formed by, for example, a dry nitrogen gas, and a plurality of stages 11 are arranged side by side in the left-right direction on the front side of the normal pressure atmosphere transfer chamber 61. In addition, the front wall of the atmospheric pressure transfer chamber 61 is provided with doors 13, similar to the side wall of the carrier block D1 of the coating/developing apparatus 1, and the lids of the carriers C on the stages 11 may be removably attached to the doors. The normal pressure transfer chamber 61 is provided with a normal pressure transfer mechanism 62 that includes a liftable multi-jointed arm.

An alignment chamber 63 configured to optically detect the orientation and center of a wafer W is provided on the left wall of the normal pressure transfer chamber 61 when viewed from the stages 11, and when a wafer W is unloaded from the alignment chamber 63, the wafer W is received at a predetermined position of the normal pressure transfer mechanism 62 at a predetermined orientation. A buffer module 64 having the same configuration as the above-described buffer module 4 is provided on the right wall. The above-mentioned normal pressure transfer mechanism 62 transfers the wafers W among the carriers C on the stages 11, the buffer module 64, the alignment chamber 63, and load-lock chambers 66A and 66B, which will be described later.

On the side (rear side) opposite to the stages 11 in the normal pressure transfer chamber 61, two load-lock chambers 66A and 66B are arranged side by side, and on the rear side of the load-lock chambers 66A and 66B, a vacuum transfer chamber 67 is arranged. Door valves 68 are interposed between the load-lock chambers 66A and 66B and the normal pressure transfer chamber 61, and gate valves 69 are interposed between the load-lock chambers 66A and 66B and the vacuum transfer chamber.

The load-lock chambers 66A and 66B are each provided with a stage on which a wafer W is placed. The stage includes pins that protrude and retract from the top surface of the stage to raise and lower the wafer W so that the wafer W can be delivered to each of the normal pressure transfer mechanism 62 and the vacuum transfer mechanism 75. In addition, the load-lock chambers 66A and 66B can be switched between a vacuum atmosphere and an air atmosphere by independently performing each of the supply and exhaust of N₂ gas in a state in which the door valve 68 and the gate valve 69 are both closed.

The vacuum transfer chamber 67 has a vacuum atmosphere at a predetermined pressure. A resist film forming module 71, a film removing module 72, a heating module 73, and a vacuum buffer module 74 are connected to the vacuum transfer chamber 67 via gate valves 70, respectively. The vacuum transfer chamber 67 is provided with a vacuum transfer mechanism 75 configured with multi-jointed arms so that the wafer W can be delivered to each of the resist film forming module 71, the film removing module 72, the heating module 73, the vacuum buffer module 74, and the load-lock chambers 66A and 66B. The above-mentioned door valves 68 and gate valves 69 and 70 are closed except when necessary to transfer the wafer W, and partition respective modules.

The resist film forming module 71 includes a chamber configured to accommodate the wafer W, a stage provided in the chamber, a temperature adjustment part, such as a heater, configured to adjust the temperature of the wafer W on the stage to a desired temperature, and a gas supply, such as a gas shower head, configured to supply a processing gas to the wafer W on the stage. A vacuum atmosphere at a predetermined pressure is formed inside the chamber, and a resist film is formed on the surface of the wafer W by ALD or CVD using a processing gas as a film forming gas. In addition, a plasma forming mechanism may be provided so that the processing gas is plasmarized to perform processing. The stage includes lifting pins like the stages in the load-lock chambers 66A and 66B so that the wafer W can be delivered to the vacuum transfer mechanism 75.

The film removing module 72 and the heating module 73 will be described, focusing on the differences from the resist film forming module 71. The film removing module 72 is a module configured to limitedly remove the resist film formed on an unnecessary portion of a wafer W. Specifically, the film removing module 72 removes the resist film on the peripheral edge of the front surface of the wafer W and an unintentionally formed resist film on the rear surface of the wafer W. For this purpose, in the film removing module 72, an etching gas is supplied as a processing gas instead of a film forming gas.

For example, the gas supply is configured such that the processing gas ejection ports open limitedly to the peripheral edge of the front surface of the wafer W. For example, the film removing module 72 is configured such that exhaust on the rear side of the wafer W is performed while the processing gas is supplied, so that some of the processing gas flows around from the peripheral edge of the front surface of the wafer W to the bottom surface. By configuring the module in this way, the etching gas is supplied limitedly to the peripheral edge and the rear surface of the wafer W, so that the above-mentioned limited removal of the film is performed.

The heating module 73 is a module configured to perform PAB, and for example, a N₂ gas is supplied into the chamber instead of the processing gas. Further, in the N₂ gas atmosphere, the wafer W on the stage is heated to a predetermined temperature, and PAB is performed.

The vacuum buffer module 74 includes a chamber in which the N₂ gas atmosphere is formed by being supplied with a N₂ gas and a vacuum atmosphere is formed by exhaust, and a shelf. This shelf is provided with supports 43 in multiple stages, for example like the buffer module 4, and a large number of slots are formed in the shelf. For example, this shelf can be raised and lowered by being connected to a lifting mechanism, and delivery of wafers W is performed between an arbitrary slot and the vacuum transfer mechanism 75 by raising and lowering the shelf. Like the buffer module 4, the vacuum buffer module 74 is used to put wafers W on standby when an abnormality is detected.

### [Substrate Transfer Path in Apparatus of Second Embodiment]

A wafer transfer path in the substrate processing apparatus 6 will be described. The wafer W unloaded from the carrier C on the stage 11 is transferred in the order of the normal pressure transfer chamber 61, the alignment chamber 63, the normal pressure transfer chamber 61, the load-lock chamber 66A, and the vacuum transfer chamber 67. Thereafter, the wafer W is transferred in the order of the resist film forming module 71, the vacuum transfer chamber 67, the film removing module 72, the vacuum transfer chamber 67, the heating module 73, and the vacuum transfer chamber 67 so that formation of the resist film, removal of an unnecessary portion of the resist film, and PAB are performed in that order. Subsequently, the wafer W is transferred in the order of the load-lock chamber 66B, the buffer module 64, and the carrier C. Supply and exhaust of the N₂ gas are performed with respect to the carrier C so that the N₂ gas atmosphere is formed inside the carrier C until the wafer W is returned and retracted from the stage 11.

### [Transfer Upon Detecting Abnormality and Effect of Transfer]

Let's suppose that, regarding a wafer W on which the resist film has been formed in the resist film forming module 71 and which is before being transferred to the load-lock chamber 66B, an abnormality that transfer to the next transfer destination on the above-mentioned transfer path is impossible due to reasons such as a temporary trouble in a module or non-vacancy of a module occurs. In such a case, the wafer W is transferred to the vacuum buffer module 74 instead of being transferred to the next transfer destination and is put on standby in the vacuum buffer module 74 until the transfer to the next transfer destination becomes possible. Specifically, a wafer W processed by the resist film forming module 71, a wafer W processed by the film removing module 72, and a wafer W processed by the heating module 73 are transferred to the vacuum buffer module 74 unless the film removing module 72, the heating module 73, and the load-lock chamber 66B are vacant. Each module that serves as a transfer source for the processed wafer W corresponds to a first placement part, each module that serves as the transfer destination for the processed wafer W and the load-lock chamber 66B corresponds to a second placement part, and the buffer module 74 is a standby chamber. Regarding whether to perform such transfer to the vacuum buffer module 74, as in the coating/developing apparatus 1, the controller 10 determines whether transfer to a transfer destination is possible and executes the transfer depending on a determination result.

It is considered that in a vacuum atmosphere, a dehydration reaction occurs in the resist film, and deterioration proceeds. Therefore, by putting the wafer W on standby in the vacuum buffer module 74 as described above, deterioration of the resist film due to the stagnation in transferring the wafers is also suppressed in the substrate processing apparatus 6 as well, as in the coating/developing apparatus 1.

In addition, in the present example, since the N₂ gas atmosphere is formed in the normal pressure transfer chamber 61, the air atmosphere is suppressed from being formed in the carrier C even when the lid of the carrier C is open. Thus, the buffer module 64 connected to the normal pressure transfer chamber 61 may be omitted. However, when the normal pressure transfer chamber 61 has the air atmosphere therein, it is preferable to provide the buffer module 64. More specifically, the carrier C on the stage 11 can have the N₂ gas atmosphere therein, but when the lid of the carrier C is opened, the atmosphere in the normal pressure transfer chamber 61 flows into the carrier C, and the concentration of the N₂ gas in the carrier C may become relatively low. Therefore, by allowing a plurality of wafers W to stay in the buffer module 64 and making the normal pressure transfer mechanism 62 to continuously return the wafers W to the carrier C at appropriate timings, the lid is prevented from being opened for a long time. As a result, deterioration of the resist films can be suppressed more reliably in the substrate processing apparatus 6. In this case, it can be said that the transfer path is changed in anticipation of an abnormality that the concentration of the N₂ gas in the carrier C corresponding to the second placement part will become low. Each of the normal pressure transfer mechanism 62 and the vacuum transfer mechanism 75 constitutes a substrate transfer apparatus together with the controller 10.

### [Configuration of Apparatus of Third Embodiment]

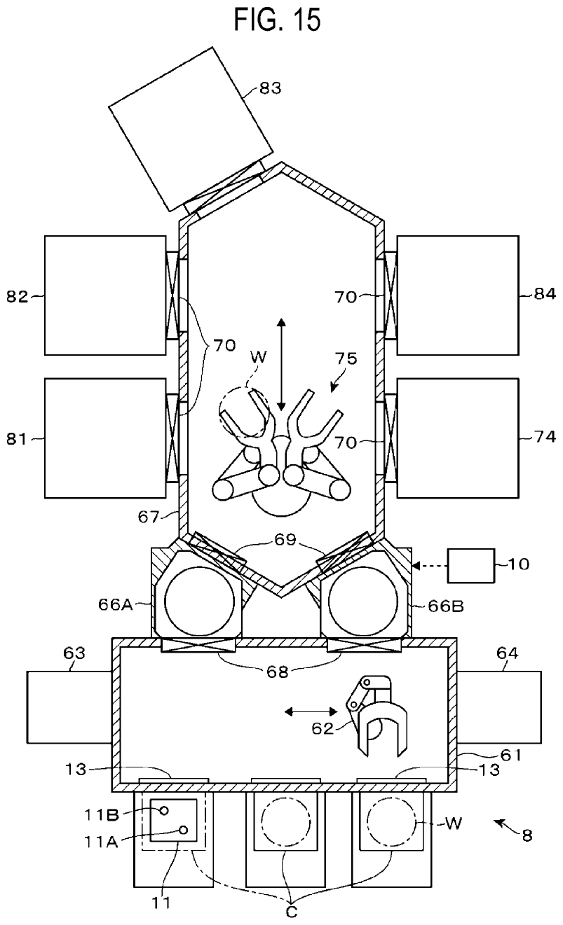

A substrate processing apparatus 8 according to a third embodiment will be described with reference to a plan view of FIG. 15, focusing on the differences from the substrate processing apparatus 6 according to the second embodiment. A wafer W on which a resist film has been exposed is transferred to the substrate processing apparatus 8, and the processing from the first PEB to the second development is performed in a vacuum atmosphere. The substrate processing apparatus 8 has almost the same configuration as the substrate processing apparatus 6, except that the modules connected to the vacuum transfer chamber 67 are different, and a heating module 81, a developing module 82, a heating module 83, a developing module 84, and a vacuum buffer module 74 are provided. The heating module 81 has a similar configuration to the heating module 73 for PAB. The developing modules 82 and 84 have substantially the same configuration as the resist film forming module 71, but respectively perform pattern formation and shaping by supplying a developing gas to the wafer W as a processing gas.

In the substrate processing apparatus 8, the wafer W unloaded from the carrier C is transferred in the order of the buffer module 64, the alignment chamber 63, and the load-lock chamber 66A. Further, the wafer W transferred from the load-lock chamber 66A to the vacuum transfer chamber 67 is transferred via the vacuum transfer chamber 67 in the order of the heating module 81, the developing module 82, the heating module 83, and the developing module 84. As a result, the first PEB, the first development, the second PEB, and the second development are sequentially performed on the wafer W. The wafer W unloaded from the developing module 84 is transported in the order of the load-lock chamber 66B and then the carrier C. When the wafer W in each of the load-lock chamber 66A, the heating module 81, the developing module 82, and the heating module 83 cannot be transferred to the next transfer destination, the wafer W is transferred to the vacuum buffer module 74 and is then transferred to the next transfer destination.

The normal pressure transfer chamber 61 may have an air atmosphere therein as described in the second embodiment. In that case, the time the wafer W stays in the carrier C in which the concentration of the N₂ gas becomes relatively low may be reduced by transferring all the wafers W from the carrier C to the buffer module 64 connected to the normal pressure transfer chamber 61, and then transferring the wafers W from the buffer module 64. In this case, it can be said that the transfer path is changed in anticipation of an abnormality that the concentration of the N₂ gas in the carrier C corresponding to the first placement part will become low.

In addition, in a case of forming the air atmosphere in the normal pressure transfer chamber 61, as in the case of the vacuum buffer module 74, an operation may be performed such that the wafer W is transferred to the buffer module 64 when a transfer abnormality is detected. Specifically, when no abnormality is detected, the wafer W unloaded from the carrier Cis transferred in the order of the alignment chamber 63, the load-lock chamber 66A, and the vacuum transfer chamber 67, and is then transferred to each processing module such as the heating module 81. As described above, when the wafer W cannot be transferred from one of the load-lock chamber 66A, the heating module 81, the developing module 82, and the heating module 83 to the next transfer destination, the wafer W is transferred from the alignment chamber 63 to the buffer module 64 and is put on standby. Further, after the abnormality is resolved, the wafer is processed while being transferred in the order of the buffer module 64, the load-lock chamber 66A, and the vacuum transfer chamber 67. Therefore, in this example, the carrier C and the alignment chamber 63 are the transfer sources for the buffer module 64, and can be considered as a first placement part. In this way, the apparatus may be configured such that the carrier C corresponds to the first placement part. In addition, the buffer module 64 may be provided in the carrier block D1 of the developing apparatus of the first embodiment, and the same operation may be performed.

The substrate to be transferred is not limited to a wafer, but may be another substrate such as a substrate for manufacturing a flat panel display. Further, although the transfer control of the wafer W on which the resist film is formed by using the MOR has been described, the wafer W on which a film is formed by using a metal-containing resist other than the MOR can also be transferred by using the above-described transfer control. It should be considered that the embodiments disclosed herein are exemplary in all respects and not restrictive. The above-described embodiments may be omitted, replaced, modified, and combined in various forms without departing from the scope and spirit of the appended claims.

The present disclosure is capable of suppressing deterioration of a metal-containing resist film formed on a substrate.

While certain embodiments have been described, these embodiments have been presented by way of example only, and are not intended to limit the scope of the disclosures. Indeed, the embodiments described herein may be embodied in a variety of other forms. Further, various omissions, substitutions and changes in the form of the embodiments described herein may be made without departing from the spirit of the disclosures. The accompanying claims and their equivalents are intended to cover such forms or modifications as would fall within the scope and spirit of the disclosures.

What is claimed is:

1. A substrate transfer method of transferring a substrate on which a metal-containing resist film is formed from a first placement part to a second placement part, the method comprising:
transferring, depending on an abnormality in a transfer path, the substrate to a standby chamber in which a second atmosphere different from a first atmosphere of the first placement part is formed, without transferring the substrate to the second placement part, and putting the substrate on standby in the second atmosphere.

2. The substrate transfer method of claim 1, wherein the metal-containing resist film is a metal oxide resist film, and the second atmosphere is an inert gas atmosphere.

3. The substrate transfer method of claim 1, wherein the first atmosphere is an atmosphere that promotes a reaction of the metal-containing resist film compared to the second atmosphere.

4. The substrate transfer method of claim 1, further comprising:
transferring the substrate to an exposure machine provided on the transfer path; and
transferring the substrate, which is transferred from the first placement part and which is immediately before being transferred to the exposure machine in the transfer path, to the second placement part and adjusting a temperature of the substrate.

5. The substrate transfer method of claim 4, further comprising:
detecting, as the abnormality, stagnation in transferring the substrate in a section subsequent to the second placement part in the transfer path.

6. The substrate transfer method of claim 1, further comprising:
transferring the substrate in a module other than the first placement part provided on the transfer path to the standby chamber depending on a type of a detected abnormality.

7. The substrate transfer method of claim 1, wherein the standby chamber comprises a plurality of standby chambers, and when the abnormality occurs in one standby chamber, the substrate is transferred to another standby chamber.

8. The substrate transfer method of claim 1, wherein one or more substrates are provided for each of the first placement part and the standby chamber, and
wherein a total number of substrates that can be accommodated in the standby chamber is greater than or equal to a total number of substrates that can be accommodated in the first placement part.

9. The substrate transfer method of claim 1, wherein the transfer path is a path formed by a processing block configured to perform at least one of forming and developing the metal-containing resist film, and an interface block interposed between the processing block and an exposure machine that exposes the metal-containing resist film, and
wherein the first placement part, the second placement part, and the standby chamber are provided in the interface block.

10. The substrate transfer method of claim 1, further comprising:
stopping transferring the substrate to a film forming module configured to form the metal-containing resist film on the transfer path when the abnormality is detected.

11. The substrate transfer method of claim 1, further comprising:
transferring the substrate on which the exposed metal-containing resist film is formed on the transfer path in an order of a first post-exposure heating module, a first developing module, a second post-exposure heating module, and a second developing module to repeat post-exposure heating and development,
wherein the substrate, which is transferred from the first developing module and which is before being transferred to the second post-exposure heating module, is transferred to the standby chamber.

12. The substrate transfer method of claim 1, wherein a resist film forming module configured to form the metal-containing resist film on the substrate is included as the first placement part or a module at a stage subsequent to the first placement part in the transfer path, and
wherein the method further comprises:
stopping transferring the substrate to the resist film forming module when the abnormality is detected.

13. The substrate transfer method of claim 1, wherein the transfer path is provided with an atmosphere-controlled module in which an atmosphere different from the first atmosphere is formed, and the atmosphere-controlled module includes the standby chamber, and
wherein the method further comprises:
performing a transfer control on a plurality of substrates such that a time during which the substrates do not stay in the atmosphere-controlled module in the transfer path is matched among the plurality of substrates.

14. The substrate transfer method of claim 1, wherein the first atmosphere is a vacuum atmosphere, and the second atmosphere is an inert gas atmosphere.

15. The substrate transfer method of claim 1, wherein the putting the substrate on standby is performed when an abnormality that the substrate cannot be transferred to the second placement part is detected.

16. The substrate transfer method of claim 1, wherein the putting the substrate on standby is performed depending on an abnormality anticipated regarding the first placement part.

17. The substrate transfer method of claim 1, wherein the putting the substrate on standby is performed depending on an abnormality anticipated regarding the second placement part.

18. A substrate transfer apparatus comprising:
a transfer mechanism configured to transfer a substrate on which a metal-containing resist film is formed in a transfer path from a first placement part to a second placement part; and
a controller configured to control an operation of the transfer mechanism depending on an abnormality in the transfer path such that, in order to put the substrate on standby in a standby chamber in which a second atmosphere different from a first atmosphere of the first placement part is formed, the transfer mechanism transfers the substrate to the standby chamber without transferring the substrate to the second placement part.
